(19) United States
(12) Patent Application Publication
(10) Pub. No.: US 2026/0123423 A1
(43) Pub. Date: Apr. 30, 2026

(54) APPARATUS AND METHODS FOR COOLING OF AN INTEGRATED CIRCUIT

(71) Applicants: Systemex Energies Inc., Laval (CA); East West Manufacturing, LLC, Atlanta, GA (US); SOCPRA Sciences et Genie S.E.C., Sherbrooke (CA)

(72) Inventors: Julien Sylvestre, Sherbrooke (CA); Omidreza Ghaffari, Sherbrooke (CA); Chady Al Sayed, Sherbrooke (CA); Seyedyaser Nabavilarimi, Sherbrooke (CA); Francis Grenier, Laval (CA); Simon Jasmin, Montreal (CA)

(21) Appl. No.: 19/429,629

(22) Filed: Dec. 22, 2025

Related U.S. Application Data
(63) Continuation of application No. 18/005,177.
(60) Provisional application No. 63/053,699, filed on Jul. 19, 2020.

(51) Int. Cl. H10W 40/47; H10W 40/25

(52) U.S. Cl. CPC H10W 40/47; H10W 40/257; H10W 40/258

(57) ABSTRACT

Systems and methods for cooling an Integrated Circuit (IC) are provided. In one embodiment, the system includes a vessel for holding a coolant in a liquid phase, where the IC is at least in part thermally coupled to the coolant via a heat transfer surface to transfer heat generated by the IC to the coolant. The heat transfer surface has a porous surface exhibiting a gradient of porosity and/or particle size along at least one direction of the heat transfer surface.

### CROSS-REFERENCE TO RELATED APPLICATIONS

This application is a continuation application of and claims the benefit of priority to U.S. application Ser. No. 18/005,177, filed on Jan. 11, 2023, which is the National Stage Application of International Application No. PCT/CA2021/050997, filed Jul. 19, 2021, which claims priority under 35 USC § 119 (e) to U.S. Patent Application Ser. No. 63/053,699, filed on Jul. 19, 2020, the entire contents of which are hereby incorporated by reference.

### FIELD OF THE INVENTION

The invention generally relates to cooling of integrated circuits and more particularly to apparatus and methods for cooling of an integrated circuit by use of a liquid coolant.

### BACKGROUND

The amount of power an integrated circuit (IC) produces fluctuates based on computational workload of the IC. In general, an increase in power results in an increase in temperature of the IC and in particular an increase in the transistors junction temperature. As the junction temperature increases so does the probability of getting logic errors in the IC and after a certain temperature the IC can no longer be expected to function properly. Thus, when there is a high computational workload of an IC, there is a desire to ensure that the IC functions properly by controlling the temperature of the IC.

One conventional method for controlling the temperature of an IC includes monitoring the IC's temperature with a thermal sensor and adjusting the speed of a fan directed to a heat sink coupled to the IC accordingly. Another conventional method for controlling the temperature of an IC includes monitoring the IC's temperature and lowering the clock frequency of the IC accordingly when the temperature increases.

However, the computing power of ICs is generally limited by thermal management issues and as such when it is desirable for an IC to be processing at a high computational workload, conventional methods for controlling the temperature of ICs may not allow for adequate temperature control that ensure that the IC functions properly while still meeting the desired high computational workload.

In light of the above, there is a need for improving the way that the temperature of ICs is managed and/or the manner in which ICs are cooled.

### SUMMARY

In accordance with one embodiment there is provided a system for cooling an integrated circuit (IC). The system comprises a closed vessel for holding a coolant in a liquid phase, the vessel being delimited at least in part by a heat transfer region, the heat transfer region being thermally-coupled with at least one surface of the IC. The system also comprises a heat-releasing element. The heat transfer region comprises a porous layer, the porous layer exhibiting a gradient of at least one of a porosity and a pore size distribution along at least one dimension of the heat transfer region.

In accordance with another embodiment there is provided a system for cooling an integrated circuit (IC). The system comprises a closed vessel for holding a coolant in a liquid phase and a heat-releasing element. The heat transfer from the IC to the liquid coolant occurs via at least one heat transfer region having a thermal resistance, the heat transfer region being integral with the IC.

In accordance with another embodiment there is provided a system for cooling an integrated circuit (IC). The system comprises a closed vessel for holding a coolant in a liquid phase, the vessel being delimited at least in part by a heat exchange surface, the heat exchange surface being thermally-coupled with at least one surface of the IC, The system also comprises a heat-releasing element. The heat exchange surface has a thermal resistance of no more than about 0.4 degree Celsius per watt for an IC power of about 45 watts.

In accordance with another embodiment there is provided a system for cooling an integrated circuit (IC). The system comprises a closed vessel for holding a coolant in a liquid phase, the vessel being delimited at least in part by a heat exchange surface, the heat exchange surface being thermally-coupled with at least one surface of the IC, The system also comprises a heat-releasing element. The heat exchange surface has a thermal resistance of no more than about 0.36 degree Celsius per watt for an IC power of about 67 watts.

In accordance with another embodiment there is provided a system for cooling an integrated circuit (IC). The system comprises a closed vessel for holding a coolant in a liquid phase, the vessel being delimited at least in part by a heat exchange surface, the heat exchange surface being thermally-coupled with at least one surface of the IC, The system also comprises a heat-releasing element. The heat exchange surface has a thermal resistance of no more than about 0.33 degree Celsius per watt for an IC power of about 88 watts.

In accordance with another embodiment there is provided a system for cooling an integrated circuit (IC). The system comprises a closed vessel for holding a coolant in a liquid phase, the vessel being delimited at least in part by a heat exchange surface, the heat exchange surface being thermally-coupled with at least one surface of the IC. The system also comprises a heat-releasing element. The heat exchange surface has a thermal resistance of no more than about 0.29 degree Celsius per watt for an IC power of about 110 watts.

In accordance with another embodiment there is provided a system for cooling an integrated circuit (IC). The system comprises a closed vessel for holding a coolant in a liquid phase, the vessel being delimited at least in part by a heat transfer region, the heat transfer region being thermally-coupled with at least one surface of the IC. The vessel comprises at least one valve. The system also comprises a heat-releasing element comprising at least one fan. The system also comprises a controller configured for operating the IC at a first IC parameter and deactivating the least one fan. The controller is also configured to control a pressure within the vessel such that the pressure within the vessel is within a first pressure P1 and a second pressure P2. The system is also configured to operate the IC at a second IC parameter and activating the least one fan. The system is also configured to turn the IC off when the pressure within the vessel reaches a third pressure P3.

### BRIEF DESCRIPTION OF THE DRAWINGS

A detailed description of embodiments of the invention is provided below, by way of example only, with reference to the accompanying drawings, in which:

FIG. 1 shows a block diagram of a system for cooling an integrated circuit (IC) in accordance with a non-limiting embodiment;

FIG. 2A shows a cross-sectional front view of the cooling system of FIG. 1 in accordance with a non-limiting embodiment;

FIG. 2B shows a perspective view of the cooling system of FIG. 1 in accordance with another non-limiting embodiment;

FIG. 2C shows a cutaway view of the cooling system of FIG. 2B in accordance with a non-limiting embodiment;

FIGS. 3A-3C show block diagrams of a controller in accordance with various non-limiting embodiments;

FIGS. 4A, 4B, 4C and 4D show various states of a coolant in accordance with a non-limiting embodiment;

FIG. 5 illustrates a steady state heat flux curve in accordance with a non-limiting embodiment;

FIGS. 6A-6C show scanning electron microscopy images of a porous layer in accordance with an embodiment, taken: in a middle of the layer in the z direction (A); at a top of the layer in the z direction and in a center of the layer in the x and y directions (B); at a top of the layer in the z direction and along an edge of the layer in either one of the x and y directions;

FIG. 7 shows a flow chart of a degassing process in accordance with a non-limiting embodiment;

FIG. 8 shows a flow chart of a decision process for modifying a power of an IC in accordance with a non-limiting embodiment;

FIG. 9 shows a flow chart of a decision process for modifying a status of a fan in accordance with a non-limiting embodiment;

FIG. 10 shows a flow chart of a decision process for modifying a pressure within the cooling system of FIG. 1 in accordance with a non-limiting embodiment;

FIG. 11 shows a flow chart of a process for assessing gas seal integrity in accordance with a non-limiting embodiment;

FIG. 12 shows a flow chart of a decision process for determining whether the process of FIG. 7 should be performed in accordance with a non-limiting embodiment; and

FIG. 13 shows pressure and power data as a function of time during the performance of the process of FIG. 7 in accordance with a non-limiting embodiment;

FIG. 14 is a perspective view of a modular cooling system for mounting on an IC (or other heat generating surface), according to a variant of the invention;

FIG. 15 is an exploded view of the modular cooling system shown in FIG. 13 from two different perspectives to show the relationship between the various components;

FIG. 16 is a plan view of two different configurations of top plates at the interface between the modular cooling system shown in FIGS. 14 and 15.

FIG. 17 is a front view of a degassing device for use with the cooling system according to the present invention;

FIG. 18 is a side view if the degassing device shown in FIG. 17;

FIG. 19 is an image analysis from a cross section of a MuSEP coating at the heat-transfer interface between the IC and the cooling system according to the present invention.

FIG. 20 is an enlarged top view of the coating shown in FIG. 19;

FIG. 21 shows the pores distribution in the coating (the pores are shown in white color);

FIG. 22 is an enlarged cross-sectional view of an IC showing the coating of FIGS. 19, 20 and 21 applied directly on the silicon die of the IC,

FIG. 23 is a plan view of the IC with the coating applied on the silicon die of FIG. 22,

FIG. 24 is a schematical view of a cooling system according to another variant.

It is to be expressly understood that the description and drawings are only for the purpose of illustrating certain embodiments of the invention and are an aid for understanding. They are not intended to be a definition of the limits of the invention.

### DETAILED DESCRIPTION

In general, a cooling system is provided for cooling an integrated circuit that is at least in part thermally coupled to a liquid coolant that is held in a vessel. A method for cooling an integrated circuit using the cooling system is also provided. Examples of implementation are illustrated in the annexed drawings and further described below.

According to one non-limiting embodiment, the cooling system includes a sealed vessel extending between an integrated circuit and a heat sink. A liquid coolant is provided within the vessel, the coolant having specific thermal properties that cause the coolant to absorb latent heat that is generated by the integrated circuit and evaporate from a liquid to a vapor at a surface in contact with the integrated circuit during its operation. The properties of the coolant also cause the coolant to condense from the vapor back to the liquid when the vapor contacts the heat sink, thus releasing the latent heat from the vapor to the heat sink.

In the following description, specific exemplary embodiments in which the disclosure may be practiced are described in sufficient detail to enable those skilled in the art to practice the disclosed embodiments. For example, specific details such as specific, structures, elements, and connections have been presented herein. However, it is to be understood that the specific details presented need not be utilized to practice embodiments of the present disclosure. It is also to be understood that other embodiments may be utilized and that logical, architectural, programmatic, mechanical, electrical and other changes may be made without departing from general scope of the disclosure.

References within the specification to “one embodiment,” “an embodiment,” “embodiments”, or “one or more embodiments” are intended to indicate that a particular feature, structure, or characteristic described in connection with the embodiment is included in at least one embodiment of the present disclosure. The appearance of such phrases in various places within the specification are not necessarily all referring to the same embodiment, nor are separate or alternative embodiments mutually exclusive of other embodiments. Further, various features are described which may be exhibited by some embodiments and not by others. Similarly, various requirements are described which may be requirements for some embodiments but not other embodiments.

It is understood that the use of specific component, device and/or parameter names and/or corresponding acronyms thereof, such as those of the executing utility, logic, and/or firmware described herein, are for example only and not meant to imply any limitations on the described embodiments. The embodiments may thus be described with different nomenclature and/or terminology utilized to describe the components, devices, parameters, methods and/or functions herein, without limitation. References to any specific protocol or proprietary name in describing one or more elements, features or concepts of the embodiments are provided solely as examples of one implementation, and such references do not limit the extension of the claimed embodiments to embodiments in which different element, feature, protocol, or concept names are utilized. Thus, each term utilized herein is to be given its broadest interpretation given the context in which that terms is utilized.

### Cooling System

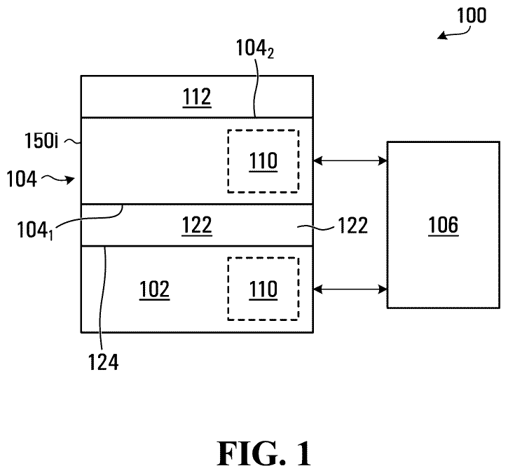

FIG. 1 shows a cooling system 100 for cooling an integrated circuit (IC) 102 in accordance with a first non-limiting embodiment. The cooling system 100 notably comprises a vessel 104 for holding a liquid coolant 108, a heat sink 112, a controller 106 and an optional sensor 110. The vessel 104 is in thermal communication with the IC 102 as well as the heat sink 112, as further described below.

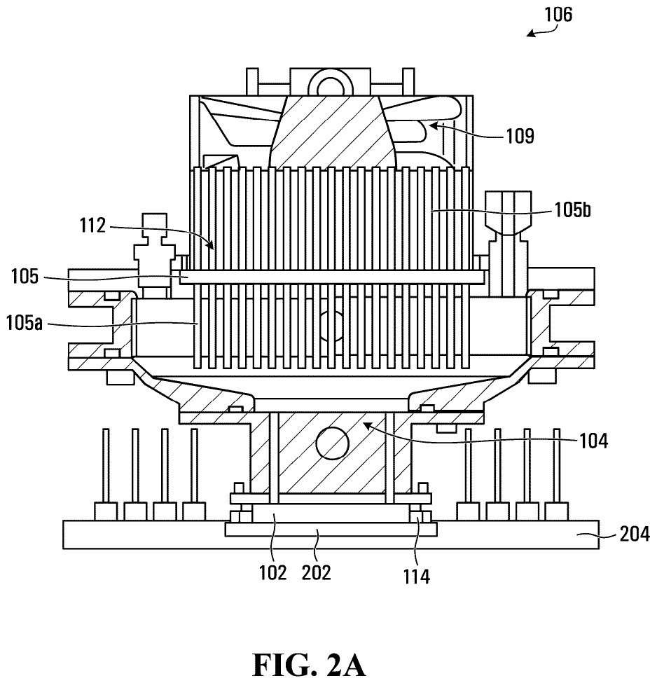

The IC 102 may be implemented using any suitable hardware components for implementing a central processing unit (CPU) including a microcontroller, field-programmable gate array (FPGA), application-specific integrated circuit (ASIC), digital signal processor (DSP), graphics processing unit (GPU), any other suitable semiconductor device, or any other suitable device. The IC 102 may be configured such that when it is running (e.g., powered on and in operation) it may process various data. The IC 102 may be suitable for a server, such as in servers running in data centers. When the IC 102 is running, it produces heat based on a number of factors including the voltage level, the clock/frequency speed/rate, and/or the workload of the IC 102. As such, when the IC 102 is running, the temperature of the IC 102 is based at least in part on the heat produced by the IC 102. As the temperature of the IC 102 increases, a critical temperature may be reached, at which the IC 102 must be shut down or throttled down to prevent it from overheating. With further reference to FIG. 2, in some non-limiting examples, the IC 102 may be packaged in a module. The module may include the IC 102, a substrate 202, as well as other structural elements (e.g., solder joints, underfill material, etc.), the module being itself attached to an electronic device 204, such as a motherboard via a socket (not illustrated). As such, the IC 102 may be associated with various electronic components external to the IC 102 and connected via the electronic device 204.

In this first embodiment, the vessel 104 comprises a heat absorbing surface 104₁, a heat releasing surface 104₂ and a plurality of walls 150ᵢ, as further described below. In terms of its composition, the vessel 104 may be made of any suitable material, or combination of materials, as it will be readily appreciated that the heat absorbing surface 104₁, the heat releasing surface 104₂ and the plurality of walls 150; may be made of the same material or they may be made of different materials. For example, the heat absorbing surface 104₁ and the heat releasing surface 104₂ may be made of a material that generally facilitates and/or improves heat transfer, while the plurality of walls may be made of a separate material that impedes, rather than facilitates, heat transfer. In one non-limiting example, the vessel 104 may be made of a first material, the first material being a metallic material that generally isolates the IC 102 from external electromagnetic interferences, such as but not limited to stainless steel. In another non-limiting example, the first material may be a composite material along with a suitable electromagnetic shielding, such as copper meshing. Taken together, the heat absorbing surface 104₁, the heat releasing surface 104₂ and the plurality of walls 1051 define an inner compartment that is sealed during use, that is the inner compartment of the vessel 104 has a fixed volume such that the coolant 108 is prevented from escaping the vessel 104 when the coolant 108 is in a gaseous phase. A pressure within the vessel 104 once the vessel has been loaded with the liquid coolant 108 and the vessel 104 has been sealed may be less than atmospheric pressure and it will be appreciated that the pressure within the vessel 104 will vary at least in part based on the particular coolant being used and the operational parameters of the system (i.e., coolant temperature, etc.). In some non-limiting examples the pressure within the vessel 104 may be less than about 30 psia, in some cases less than about 27.5 psia, in some cases less than about 25 psia, in some cases less than about 22.5 psia, in some cases less than about 20 psia, in some cases less than about 17.5 psia, in some cases less than about 15 psia, in some cases less than about 12.5 psia, in some cases less than about 10 psia, in some cases less than about 8.5 psia and in some cases even less. It will be readily appreciated that, in use, given that the vessel 104 defines a sealed inner compartment having a fixed volume, the pressure within the vessel 104 will vary according to the operational parameters (i.e., load, temperature, etc.) of the IC 102. It will also be readily appreciated that the pressure within the vessel 104 will directly impact the boiling point of the coolant 108 used, as further described below. The vessel 104 may also include at least one pressure valve (not shown)—the pressure valve may be configured to be opened manually or automatically. The pressure valve can notably be used to release some gas from the vessel 104 after the vessel has been sealed and set for operation, as further described below, and can therefore be used to modulate a pressure within the vessel 104.

In this non-limiting embodiment, the vessel 104 may also have any suitable shape (e.g., the vessel 104 may be generally cubic, cuboidal, cylindrical and the likes), may have any suitable size and therefore may accommodate any suitable volume of the liquid coolant 108, with the volume of liquid coolant within the vessel 104 being less than the (fixed) volume of the (sealed) compartment of the vessel 104. In some non-limiting examples, the vessel 104 may be configured to accommodate at least about 10 mL of the liquid coolant 108, in some cases at least about 20 mL of the liquid coolant 108, in some cases at least about 30 mL of the liquid coolant 108, in some cases at least about 40 mL of the liquid coolant 108, in some cases at least about 50 mL of the liquid coolant 108, in some cases at least about 60 mL of the liquid coolant 108, in some cases at least about 70 mL of the liquid coolant 108, in some cases at least about 80 mL of the liquid coolant 108, in some cases at least about 90 mL of the liquid coolant 108, in some cases at least about 100 mL of the liquid coolant 108, in some cases at least about 200 mL of the liquid coolant 108, in some cases at least about 300 mL of the liquid coolant 108, in some cases at least about 400 mL of the liquid coolant 108, in some cases at least about 500 mL of the liquid coolant 108 and in some cases even more. In other non-limiting examples, the vessel 104 may be configured to accommodate a volume of coolant per wattage of the IC 102 of at least about 0.1 mL/W, in some cases at least about 0.2 mL/W, in some cases at least about 0.3 mL/W, in some cases at least about 0.4 mL/W, in some cases at least about 0.5 mL/W, in some cases at least about 0.6 mL/W, in some cases at least about 0.7 mL/W, in some cases at least about 0.8 mL/W, in some cases at least about 0.9 mL/W, in some cases at least about 1 mL/W, in some cases at least about 1.1 mL/W, in some cases at least about 1.2 mL/W, in some cases at least about 1.3 mL/W, in some cases at least about 1.4 mL/W, in some cases at least about 1.5 mL/W and in some cases even more. Regardless of the specific means of constructing the vessel 104 and/or the size and configuration of the vessel 104, the vessel 104 is generally designed for holding the coolant 108 in a liquid phase.

Still in this non-limiting embodiment, at least part of or at least one surface 124 of the IC 102 is thermally coupled to the coolant 108 to transfer heat generated by the IC 102 to the coolant 108 via the heat absorbing surface 104₁. As such, the at least part of or at least one surface 124 may be considered a heat releasing surface of the IC 102. More specifically, the heat absorbing surface 104₁ of the vessel 104 may be a surface of the vessel 104 that is formed and/or delimited by an integrated heat spreader (IHS) 122 of the IC 102, the IHS 122 generally representing a material that is present on (a top surface of) the IC 102 to dissipate heat generated by the various components present in the IC 102 during use. The IHS 122 is therefore the region of the IC 102 at which a significant amount of heat dissipation occurs during operation of the IC 102. The inner compartment of the vessel 104 in which the liquid coolant 108 is present is therefore defined at least in part by the IHS 122. There is accordingly no direct contact between the IC 102 and the liquid coolant 108 in this non-limiting embodiment and the IC 102 is thermally coupled to the coolant 108 via the IHS 122. It will be readily appreciated that, with reference to FIG. 1, while only the external casing of the IC 102 is shown the IC 102 may in fact have any suitable external (i.e., shape, size, etc.) as well as internal configuration (i.e., number of CPUs, etc.) and heat may in fact be released via a number of distinct surfaces of the IC 102 (i.e., there may be more than one surface 124).

In this non-limiting embodiment, the vessel 104 may accordingly be made of a second material which corresponds to a material of the IHS 122. The second material may be the same as the first material, or it may be different and subjected to a variety of surface treatments to increase and/or facilitate heat transfer from the IC 102 to the liquid coolant 108, as further described below.

Still in this non-limiting embodiment, the cooling system 100 also comprises a heat sink 112 which is thermally coupled to the coolant 108 to absorb heat from the coolant 108 in a gaseous and/or liquid phase, as further described below. The heat releasing surface 104₂ of the vessel 104 may therefore be defined by the heat sink 112, which may notably take the form of a base plate 105 comprising a first plurality of extensions 105ₐ generally protruding from the base plate 105 towards the internal compartment of the vessel 104, thereby increasing the overall surface of the heat releasing surface 104₂. Upon contact between the coolant 108 and the first plurality of extensions 105ₐ, the heat sink 112 absorbs heat which is then expelled from the cooling system 100 via, in one non-limiting example, a second plurality of extensions 105_{b} that generally protrude from the base plate 105 away from the internal compartment of the vessel 104. The second plurality of extensions 105_{b} is in direct contact, and increases the surface of contact, with another fluid such as air that is flowing between the second plurality of extensions 105_{b}. Heat is therefore transferred from the second plurality of extensions 105_{b} to air such that heat is effectively expelled from the cooling system 100.

While in FIG. 2A the first plurality of extensions 105ₐ and the second plurality of extensions 105_{b} are mirror image from each other, they need not be in other non-limiting examples. That is, the first plurality of extensions 105ₐ and the second plurality of extensions 105_{b} may each have any suitable form (e.g., fins), dimensions (e.g., length, diameter) and may each be present in any suitable number so as to effectively increase the contact surface between (i) the coolant 108 and the first plurality of extensions 105ₐ (i.e., the heat releasing surface 104) and (ii) the second plurality of extensions 105_{b} and air. To further facilitate and/or increase heat transfer from the second plurality of extensions 105_{b} to air, a fan 109 may be installed on top of the second plurality of extensions 105_{b} to facilitate and/or increase air circulation between the second plurality of extensions 105_{b}. Any suitable fan, as well as any suitable number of fans, may be used, such as but not limited to a fan with an air flow velocity of at least about 30 cubic feet per minute (CFM), in some cases at least about 40 CFM, in some cases at least about 50 CFM, in some cases at least about 60 CFM, in some cases at least about 70 CFM and in some cases even more. In yet further non-limiting examples, the heat sink 112 may be modified such that another fluid (e.g., a cooling liquid) circulates between the second plurality of extensions 105_{b}.

The first plurality of extensions 105ₐ can be configured such that, in use, the liquid coolant 108 is not in direct contact with the first plurality of extensions 105ₐ and heat transfer from the coolant 108 to the first plurality of extensions 105ₐ can therefore only occur through the gaseous phase of the coolant 108. It will be readily appreciated that the configuration of the first plurality of extensions 105ₐ, as discussed above, notably includes the shape, orientation and size of the first plurality of extensions 105ₐ, and such configuration should be considered in the context of the overall shape and size of the vessel 104 as well as the volume of liquid coolant 108 that is present within the vessel 104 during use. In other non-limiting examples, the first plurality of extensions 105ₐ can also be configured such that, in use, the liquid coolant 108 is in direct contact with the first plurality of extensions 105ₐ such that heat transfer from the coolant 108 to the first plurality of extensions 105ₐ therefore occurs through both the liquid and gaseous phases of the coolant 108. In this example, the configuration of the first plurality of extensions 105ₐ, the vessel 104 and the volume of liquid coolant 108 can be chosen such that the first plurality of extensions 105ₐ are at least 10% (per volume or per surface or per length of the first plurality of extensions 105ₐ) immersed in the liquid coolant 108, in some cases at least about 20% immersed in the liquid coolant 108, in some cases at least about 30% immersed in the liquid coolant 108, in some cases at least about 40% immersed in the liquid coolant 108, in some cases at least about 50% immersed in the liquid coolant 108, in some cases at least about 60% immersed in the liquid coolant 108 and in some cases even more.

Because in this embodiment the heat releasing surface 104₂ is defined by the heat sink 112, the inner compartment of the vessel 104 is also delimited by the heat sink 112. As such, the vessel 104 may also be made of a third material which corresponds to a material of the heat sink 112. The third material may be the same as the first material and/or the second material, or it may be different. The heat sink 112, including the first plurality of extensions 105ₐ and the second plurality of extensions 105_{b}, may be made of any suitable material, for example a metallic materiel such as but not limited to aluminum, copper and the likes]. In further non-limiting examples, the first plurality of extensions 105 may be further electroplated with a coating to facilitate and/or improve condensation of the coolant 108 in a gaseous phase on the first plurality of extensions 105ₐ, the coating notably comprising any one of a copper coating, ceramic coating and the likes. Alternatively, the first plurality of extensions 105ₐ may also be coated with a hydrophobic material or channels and/or grooves may be mechanically etched onto at least a portion of the first plurality of extensions 105ₐ to further increase the contact surface between the coolant 108 and the first plurality of extensions 105ₐ.

In another non-limiting embodiment, the heat sink 112 may also be entirely substituted for a condenser 300 that is configured to condense the coolant 108 in a gaseous phase back to a liquid phase. The condenser 300 may be directly integrated within a plate that defines the heat releasing surface 104₂ and in this embodiment there are no extensions 105ₐ generally protruding away from the plate towards the inner compartment of the vessel 104. Various types and configurations of condensers may be used and the condenser configuration may also be chosen to as to accommodate at least one fan. In one non-limiting example, with further reference to FIGS. 2B and 2C, the condenser 300 may be integrated with the vessel 104, and therefore in fluid communication with the inner compartment defined by the vessel 104, via an upper region of the vessel 104. In this example, the condenser 300 is secured to the vessel 104 via two securing members 302₁, 302₂ and four threaded fasteners 303ₓ that engage an outer and upper surface 304 of the vessel 104. To ensure fluid communication between the vessel 104 and the condenser 300, there is an opening 124 in the upper region of the vessel 104 that engages an inlet 306 of the condenser 300.

While in the example of FIGS. 2B and 2C the condenser 300 is positioned generally at non-nil angle relative to a generally vertical axis, this needs not be the case in other embodiments. Similarly, the condenser 300 may also be secured to, integrated with or otherwise connected to, the vessel 104 in any suitable manner as long as there is fluid communication between the inner compartment defined by the vessel 104 and the condenser 300. The condenser 300 may have any suitable internal volume, that is the internal volume of the condenser 300 may be between about 250 mL and about 500 mL, in some cases between about 300 mL and about 450 mL, in some case between about 350 mL and about 400 mL. The condenser 300 may also have any suitable size and any suitable condensing capacity—for example the condenser 300 could be sized to accommodate a 2 U (8.9 cm) or a 4 U (17.8 cm) server rack system and the likes. The condenser 300 may also be fitted with a fan 109 to facilitate and/or increase air circulation around the condenser 300. Any suitable fan 109, as well as any suitable number of fans 109, may be used, such as but not limited to a fan with an air flow velocity of at least about 30 CFM, in some cases at least about 40 CFM, in some cases at least about 50 CFM, in some cases at least about 60 CFM, in some cases at least about 70 CFM, in some cases at least about 80 CFM, in some cases at least about 90 CFM, in some cases at least about 100 CFM, in some cases at least about 110 CFM, in some cases at least about 120 CFM, in some cases at least about 130 CFM, in some cases at least about 140 CFM, in some cases at least about 150 CFM and in some cases even more. Non-limiting examples of condensers that may be used include crossflow heat exchangers with inner grooved tubes, printed circuit heat exchangers and the likes.

While in this embodiment condensation of the coolant 108 from a gaseous phase back to a liquid phase occurs directly within the internal compartment of the vessel 104 (for example, when the heat sink 112 or the condenser 300 delimits the inner compartment of the vessel 104), this needs not be the case in other embodiments as the condenser 300 may also be remotely positioned from the vessel 104, in which case the coolant 108 may be circulated via thermosiphoning between the vessel 104 and the condenser 300. It will be readily appreciated that in this case the condenser may also act as condenser for a plurality of cooling systems 100, effectively centralizing the heat removal step for a plurality of cooling systems 100 and/or a plurality of electronic devices 204.

The cooling system 100 also comprises connection means 114 configured to secure the cooling system 100 onto the electronic device 204. Specifically, the connection means 114 create a mechanical link between the electronic device 204 and the cooling system 110, and may enable the regulation of the amount of pressure that is exerted by the cooling system 100 (i.e., the vessel 104) onto the electronic device 204 when the cooling system 100 is attached onto the electronic device 204. In other words, the mechanical link established between the electronic device 204 and the cooling system 110 (via the connection means 114) seals the inner compartment of the vessel 104 when the cooling system is secured to the electronic device 204, the IHS 122 of the IC 102 delimiting at least in part the internal compartment of the vessel 104. To this end, the connection means 114 may notably include a frame and a plurality of fasteners (e.g., threaded fasteners such as screws, bolts, rivets and the likes) configured to secure the frame to the electronic device 204. The connection means 114 may be configured to fit any suitable socket, including a CPU socket such as but not limited to a LGA2011 socket, a LGA2066 socket, a LGA 3647 socket, a GPU socket as well as any other type of socket. The connection means 114 may also include at least one electrostatic isolator to create a further dielectric barrier between the coolant 108 and the IC 102/electronic device 204 when the cooling system 100 is in use. Using the connection means 114, the cooling system 100 can be fitted onto any commercially-available IC 102/electronic device 204. Any other suitable connection means 114 may be used in other non-limiting embodiments.

The cooling system 100 may therefore be provided as a kit comprising at least the vessel 104 (exclusive of the heat absorbing surface 104₁), the heat sink 112 and the connection means 114—in this case the heat absorbing surface 104₁ of the cooling system 100 will be defined by the IHS 122 when the cooling system 100 is mounted onto the IC 102. In other embodiments, the kit may also comprise the IHS 122 and means to secure the IHS 122 to the IC 102 prior to mounting the cooling system 100 onto the IC 102.

It will be readily appreciated that the cooling system 100 is generally configured to be mounted directly onto the electronic device 204, and may be mounted onto the electronic device 204 in a localized manner such that the cooling system 100 engages only one particular IC 102 for cooling of the particular IC 102. As such, a plurality of cooling systems 100 could be used to cool various ICs 102 of a single electronic device 204. Even though the cooling system 100 uses a liquid coolant 108 to cool the IC 102, as further described below, the configuration of the cooling system 100 notably with its vessel 104 and connection mean 114 ensures that there is no contact between the liquid coolant 108 and the electronic device 204. Further, in one non-limiting embodiment there is also no contact between the liquid coolant 108 and the IC 102 since the IC 102 is thermally connected to the coolant 108 via the IHS 122. Given that during operation the pressure within the vessel 104 will change, this ensures that the cooling system 100 does not exert any additional pressure on the IC 102/the electronic device 124 in use.

### Coolant

The coolant 108 may be a liquid coolant, specifically a dielectric coolant to avoid short-circuiting the electrical connections between the IC 102 and the various associated electronic components. The liquid coolant 108 can be engineered with a specific boiling point at a temperature selected according to cooling requirements. Since the phase transition from liquid to vapor takes-up a significant amount of energy, the boiling point may be selected to be lower than the maximal operational temperature of the IC 102. In other words, if the temperature of the IC 102 progressively increases, the coolant 108 should start boiling before the point at which the critical temperature is reached and the IC 102 must be shut down or throttled down to prevent it from overheating. The temperature differential, which is the difference between the IC's 102 critical temperature, which is considered to be the upper limit of its operational temperature range and the liquid boiling temperature (e.g., the boiling point), may be determined according to the specifications of the IC 102 and of the coolant 108. It is however preferred that the boiling point of the coolant 108 be below the IC's 102 critical temperature. As such, the coolant 108 has at least one boiling point. The boiling point of the coolant 108 may be relatively low when compared to other liquids. For example, the coolant 108 when compared with water may have a lower boiling point. More specifically, in some embodiments, the maximum boiling point of the coolant is no greater than 90 degree Celsius, in some cases no greater than 80 degree Celsius, in some cases no greater than 70 degree Celsius, in some cases no greater than 60 degree Celsius, in some cases no greater than 50 degree Celsius, in some cases no greater than 40 degree Celsius, in some cases no greater than 30 degree Celsius and in some cases even less. The chemicals sold by 3M™ under the trademark Novec™ are examples of coolant 108 that may be used, such as but not limited to Novec™ 649, Novec™ 7000, Novec™ 7100 and the likes. The chemicals sold by 3M™ under the trademark Fluorinert™ are also examples of coolant 108 that may be used, such as but not limited to FC-3284, FC-72, FC-84 and the likes. The chemical sold by Dupont™ under the trademark Vertrel© are yet further examples of coolant 108 that may be used, such as but not limited to Dupont™ Vertrel© XF and the likes. Alternatively, any other liquid, even non-dielectric liquid, with a boiling temperature less than about 50° C. at 1 atm could also be used as the coolant 108.

Coolants with multiple boiling points may also be used, as notably described in International Publication No. WO 2014/040182. In a specific example, this can be achieved by mixing liquids having different boiling points. The family of Novec products referred to earlier can be engineered to provide a range of boiling points so it is a matter of selecting the proper liquid composition to provide the desired phase transition temperatures. Coolants with multiple boiling points may provide a more gradual thermal energy absorption than a liquid having a single boiling point. A single boiling point invokes a significant heat take-up mechanism and it is not a gradual process. It is rather a step process. With multiple boiling points the mechanism is more progressive. Albeit it still has a step-like nature, there are multiple steps so it is possible to operate between steps. In one non-limiting example, the liquid coolant 108 can be a mixture of two liquids of the Novec family having boiling points A and B respectively, where A is lower than B. As the temperature of the IC 102 increases, the liquid with boiling point A will undergo phase change and will provide an enhanced cooling action. The additional cooling may thus suffice to stabilize the temperature of the IC 102. Should increased cooling be further required, the fraction of the coolant with boiling point B will start changing phase. At that point, both coolant fractions will be boiling.

In another non-limiting example, the boiling points can be selected such as to straddle the operational temperature of the IC 102. In other words, during steady state operation, the IC 102 is at a temperature that exceeds the boiling point A (which is assumed to the lowest) and that coolant fraction is boiling. The fraction having boiling point B (which is the highest) starts to change phase when a higher temperature is reached. As with the previous example, the boiling point B is at or slightly below the critical temperature such as to provide additional cooling before the temperature reaches a point where the IC 102 has to be shut down.

In another non-limiting example, using coolant engineered with multiple boiling points fraction of the coolant that is still liquid may help condensate at least in part the gaseous fraction. Since the difference of temperature between the boiling points can be significant, for example in the order of 10 degrees Celsius or more, the bubbles of the evaporating fraction have to travel through the liquid medium to reach the surface of the coolant body. That liquid medium has the ability to take up more heat, as its boiling point is higher. The cooling effect provided by the coolant that is still liquid on the vapor component may, in certain circumstances, suffice to completely condensate the vapor. Thus, little or no bubbles will break the surface.

The fractions having different boiling points may have the same density, in which case they will likely mix uniformly or different densities. Different density cooling fractions may also be used when they have similar boiling points. In this situation, the body of coolant 108 in the vessel 104 may be stratified and there is a lower density fraction on top with a higher density fraction below. Assuming that the higher density fraction starts to boil first, the vapor will travel through the lighter density fraction and assuming this fraction is sufficiently cool, it will condensate at least in part the vapors.

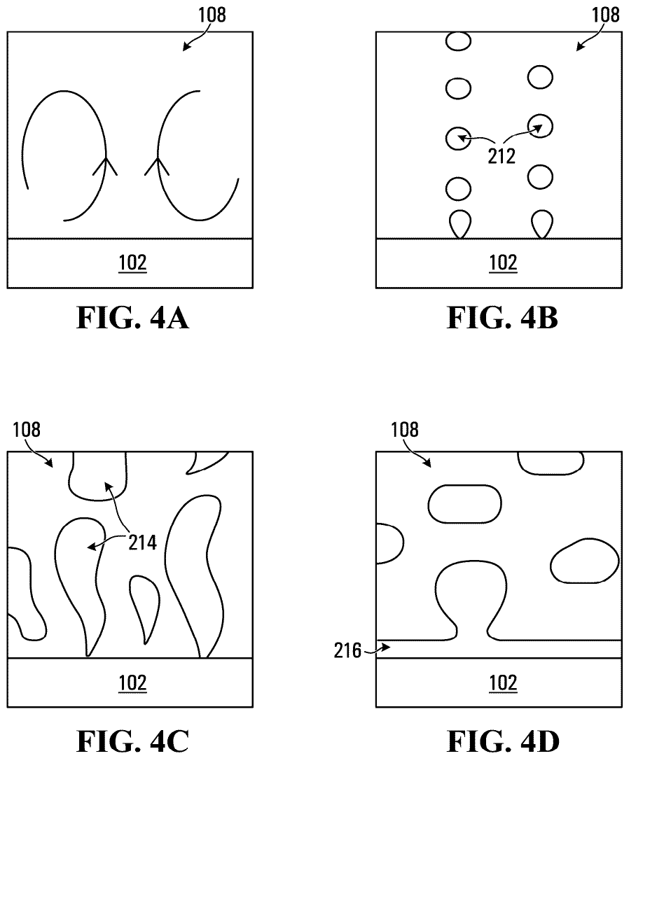

In this embodiment, the liquid coolant 108 is substantially free from non-condensable gas when the liquid coolant 108 is within the internal (and sealed) compartment of the vessel 104. Within the context of the present disclosure, non-condensable gas is understood to refer to any gas that cannot be condensed in the operating conditions of the cooling system 100, such as but not limited to air, nitrogen, hydrogen, oxygen, carbon dioxide, carbon monoxide or hydrogen sulphide. In some non-limiting examples, in use within the cooling system 100 (i.e., after a degassing protocol such as the process 700 of FIG. 7 has been performed, as further described below), a mass fraction of non-condensable gas relative to the liquid coolant in a gaseous phase in the system 100 is no more than 5%, in some cases no more than 4%, in some cases no more than 3%, in some cases no more than 2%, in some cases no more than 1.5%, in some cases no more than 1% and in some cases even less.

### Controller and Sensor

The controller 106 is configured for controlling various parameters of the cooling system 100. More specifically, the controller 106 is configured for providing control algorithms for adjusting the heat transfer capabilities of the cooling system 100. The control algorithms for adjusting the heat transfer capabilities of the cooling system 100 may include controlling one or more control parameters of the cooling system 100 and/or controlling one or more operational parameters of the IC 102 in order to adjust the temperature of the IC 102. In other non-limiting examples, the control algorithms may also include controlling one or more parameters for any controllable element of the cooling system 100, as further described below. The various aspects that the controller 106 is configured to control are discussed further throughout this document.

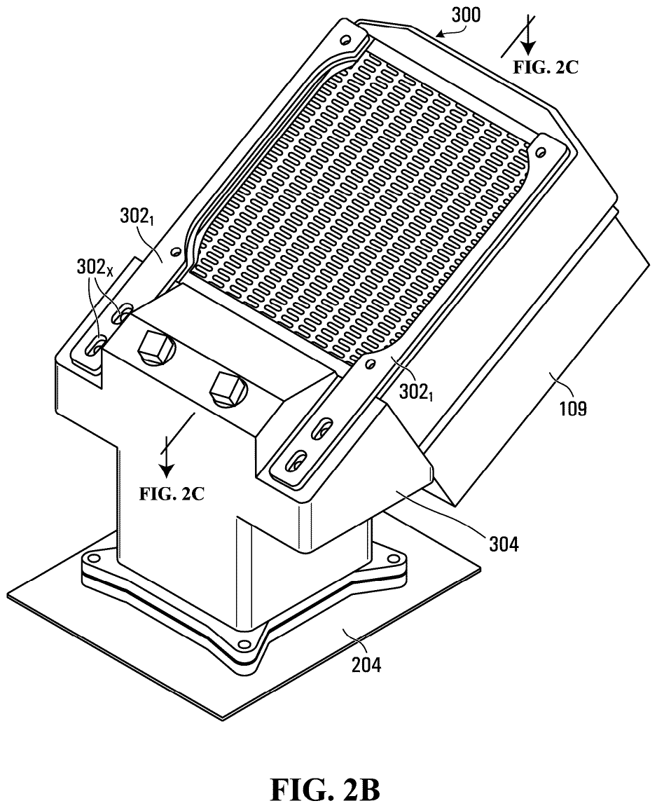

In the embodiment of FIG. 1, the controller 106 is external to the IC 102. In such cases, the controller 106 may be configured as shown in FIG. 3A. The controller 106 includes a processor 292, which is different from the IC 102, a computer readable memory 290 and input/output circuitry 294. The processor 292, the computer readable memory 290 and the input/output circuitry 294 may communicate with each other via one or more suitable data communication buses and the controller 106 communicates via one or more suitable data communication buses with the IC 102. FIG. 3B is a variant of FIG. 3A in which the controller 106 communicates with the IC 102 and at least one control component 296, as further described below. In the specific and non-limiting examples of FIGS. 3A and 3B the processor 292 is different from the IC 102; however, in other non-limiting examples the processor 292 needs not be and in fact the IC 102 can include the processor 292, for example as shown in FIG. 3C. Although in FIG. 3C the computer readable memory 290 and the input/output circuitry 294 are shown as external to the IC 102, in other embodiments the computer readable memory 290 and the input/output circuitry 294 may also be included in the IC 102 and as such the controller 106 may also be implemented on the IC 102 (i.e., the controller 106 is internal to the IC 102) in these non-limiting examples. The input/output circuitry 294 also communicates via one or more suitable data communication buses with at least one control component 296. In one non-limiting example, the control component can be any controllable element of the system, such as but not limited to the fan 109, a pressure valve and the likes.

Although the controller 106 is illustrated and discussed in this document as a digital controller, the controller 106 may be implemented as an analog controller in other embodiments. The analog controller may include various electronic components that typically would not include the processor 292 and the computer readable memory 290. In other words, the controller 106 may be implemented to perform analog signal processing which is conducted on continuous analog signals by some analog means (as opposed to the discrete digital signal processing where the signal processing is carried out by a digital process). It is appreciated that the controller 106 may include both analog and digital components in various implementations of the controller 106. For ease of readability of the rest of this document, unless specified otherwise, reference to the cooling system 100 is to be understood to be reference to the controller 106 regardless of whether the controller 106 is implemented external to the IC 102 or on the IC 102.

Turning now to the structure of the controller 106, the computer readable memory 290 may be any type of non-volatile memory (e.g., flash memory, read-only memory (ROM), magnetic computer storage devices or any other suitable type of memory) or semi-permanent memory (e.g., random access memory (RAM) or any other suitable type of memory). Although only a single computer readable memory 290 is illustrated, the controller 106 may have more than one computer readable memory module. The computer readable memory 290 stores program code and/or instructions, which may be executed by the processor 292. The program code and/or instructions executable by the processor 292 may include software implementing control algorithms for adjusting the heat transfer capabilities of the cooling system 100 (e.g., increasing and/or decreasing the heat flux supplied by the IC 102 to the coolant 108). The computer readable memory 290 may also include one or more databases for the storage of data.

The processor 292 may be implemented using any suitable hardware component for implementing a central processing unit (CPU) including a microcontroller, field-programmable gate array (FPGA), application-specific integrated circuit (ASIC), digital signal processor (DSP), integrated circuit (IC), graphics processing unit (GPU) or any other suitable device. The processor 292 is in communication with the computer readable memory 290, such that the processor 292 is configured to read data obtained from the computer readable memory 290 such as information pertaining to the control algorithms and execute instructions stored in the computer readable memory 290 such as defined by the control algorithms for adjusting the heat transfer capabilities of the cooling system 100. Although only a single processor 292 is illustrated, it is appreciated that more than one processor may be used.

The controller 106 may runs an operating system stored in the computer readable memory 290 such as Android, IOS, Windows 7, Windows 8, Linux and Unix operating systems, to name a few non-limiting possibilities. The processor 292 may execute instructions stored in the computer readable memory 290 to run the operating system such that the control algorithms for adjusting the heat transfer capabilities of the cooling system 100 can then be executed. It is appreciated that the controller 106 may be adapted to run on operating systems that may be developed in the future.

The input/output circuitry 294 may be used to communicate with the IC 102 and/or the at least one control component 296. That is, the controller 106 may transmit or receive signals via the input/output circuitry 294 to or from the IC 102. The transmitted signals from the controller 106 to the IC 102 may be one or more control signals that include control information for controlling at least one operational parameter (e.g., clock frequency, supply voltage, number of active cores, etc.) of the IC 102 that controls a rate of heat energy produced by the IC 102 and more specifically for increasing and/or decreasing the heat flux supplied by the IC 102 to the coolant 108. In other words, the control signal from the controller 106 to the IC 102 may be used to control at least one operational parameter of the IC 102 in order to control the temperature of the IC 102. The input/output circuitry 294 may also be used to communicate with the sensor 110. That is, the controller 106 may transmit or receive signals via the input/output circuitry 294 to or from the sensor 110. The received signals at the controller 106 from the sensor 110 may include information pertaining to measurements taken by the sensor 110 or a status of the sensor 110 (e.g., operational or not, etc.). The sensor 110 may be any one of a variety of sensors and may include one or more optical, acoustic, temperature, pressure, conductivity sensors and/or any other suitable sensors.

The sensor 110 may be a temperature sensor. The temperature sensor may be positioned at various locations, for example the temperature sensor may be located on the IC 102 for measuring the temperature of the IC 102, in the vessel 104 for measuring the temperature of the coolant 108 (for example, using a thermocouple), or at the level of the IHS 122 for measuring the temperature of the IHS 22. For example, the temperature sensor may be positioned near the heat absorbing surface 104₁ and used to measure the surface temperature of the IC 102 or the temperature of the coolant 108 near the heat absorbing surface 104₁. Multiple temperature sensors may also be present concurrently at various locations of the cooling system 100.

In another non-limiting embodiment, the sensor 110 may also be used to measure a state and/or phase change such as a state of the coolant 108 or various properties of the coolant 108 at the heat absorbing surface 104₁ and/or on the surface of the IC 102. For example, the sensor 110 may monitor the boiling of the coolant 108 near the heat absorbing surface 104₁. In particular, the sensor 110 observes the state of phase change of the coolant 108 from liquid to gas, by determining the morphology of the bubbles generated at the surface of the IC 102. This could include measuring the bubble density, such as the mean number of bubbles per unit area or the area of the IC surface that is occupied by bubbles. In other words, the sensor 110 may be a boiling monitor. A first example of a boiling monitor includes having a light source on one side of the surface of the IC 102, where a detector measures the amount of light from the light source being transmitted through the boiling liquid. The light source could be a LED, a LED collimated with a lens, or a laser. A second example of a boiling monitor includes having a camera with a lens assembly to image the surface of the IC 102. Image processing software measures the density of bubbles or the area of bubbles on the IC 102. The lens assembly could have a relatively shallow focal depth so that bubbles that have detached from the surface of the IC 102 do not appear sharply in the image. A third example of a boiling monitor is having an ultrasound emitter sending a pulse into the liquid and an ultrasound receiver measures the amplitude or time of arrival of the pulse. The pulse could propagate at a grazing angle to the surface of the IC 102 or it could come at a substantially sharper angle and be reflected by the surface.

The sensor 110 may also be a pressure sensor for measuring the pressure of the coolant 108 within the vessel 104. Given that the vessel 104 is closed/sealed during use, it will be readily appreciated that the pressure within the vessel 104 will change (and build up) as the temperature of the coolant 108 increases during operation of the cooling system 100.

Irrespective of its specific implementation, the sensor 110 is configured to sense either one of a temperature (of the IC 102, the IHS 122 or within the vessel 104), a pressure (within the vessel 104) and/or a state of phase change of the coolant 108 and to generate a signal, which is transmitted to the controller 106 indicative of the state of phase change of the coolant 108. The received signal from the sensor 110 to the controller 106, is then processed by the controller 106 to generate the control signal to the IC 102 for regulating the transfer of thermal energy between the IC 102 and the coolant 108.

The cooling system 100 may also include other components such as mechanisms for inducing a liquid flow within the vessel 104 and/or near the surface of the IHS 122 and/or mechanism for vibrating the IC 102 in the vessel 104. Such mechanism

The input/output circuitry 294 may be also used to communicate with the at least one control component 296. That is, the controller 106 may transmit or receive signals via the input/output circuitry 294 to or from the at least one control component 296. The at least one control component 296 may be used to adjust at least one operational parameter of the cooling system 100 that controls, among others, the temperature of the IC 102, the rate of heat energy absorbed by the coolant 108, the operational status of the fan 109 of the pressure valve and the likes. As such, the transmitted signals from the controller 106 to the control components 296 may include control information for controlling at least one operational parameter of the cooling system 100 that controls that controls, among others, the temperature of the IC 102, the rate of heat energy absorbed by the coolant 108, the operational status of the fan 109 of the pressure valve and the likes. In one non-limiting example, the at least one control component 296 can be the fan 109 in which case the signals transmitted between the controller 106 and the fan 109 may be used to activate or deactivate the fan 109, increase or decrease the RPM of the fan 109 as well as provide information to the controller 106 regarding the operational status of the fan 109 (i.e., an on/off state) as well as its RPM. In another non-limiting example, the at least one control component 296 can be a pressure valve in which case the signals transmitted between the controller 106 and the pressure valve may be used to open/close the valve as well as to provide information to the controller 106 regarding the status of the fan 109 (i.e., its open/closed state, etc.).

It is further appreciated that the cooling system 100 may be implemented in various other forms and that the examples given above are only some examples of implementation of the cooling system 100.

### Degassing

It will be readily appreciated that, at the time the liquid coolant 108 is added to the vessel 104, the addition is performed in an open vessel at atmospheric pressure. In other words, the coolant 108 will be in contact at least with air during the addition the vessel 104 and the coolant 108 will not be substantially free of non-condensable gas once added to the vessel 104. Because of such contact with air, it is also not possible to degas the coolant 108 prior to the coolant 108 being added to the vessel 104. After the vessel 104 is sealed, loaded with the coolant 108 and essentially ready to be operated, the coolant 108 needs to be degassed so as to maximize heat transfer efficiency during the operation of the cooling system 108.

In accordance with one embodiment, the cooling system 100 is configured to degas the coolant 108 directly within the vessel 104—more specifically, the cooling system 100 is configured to use at least the IC 102 as a heat source to perform a degassing protocol directly within the vessel 104. In a preferred embodiment, the degassing protocol is therefore performed before the first operation of the cooling system 100 and no further degassing should be required for as long as the cooling system 100 remains a closed system (e.g., no pressure valve is opened, the cooling system 100 retains its gas seal integrity such that there is no fluid communication at any time between the inner compartment of the vessel 104 and the ambient air, etc.).

With further reference to FIG. 7 is shown a non-limiting embodiment of a process 700 for performing a degassing protocol within the vessel 104. As such, the vessel 104 is sealed, loaded with the coolant 108 and considered essentially ready to be operated prior to the beginning of the process 700. It will be readily appreciated that the various operational parameters of the process 700 herein described will be reliant upon a variety of factors, such as but not limited to the IC type and its rated power, the configuration and size of the vessel 104, the type and size of the heat sink 112 or condenser 300 used, the type and number of fans 109 used, the type and volume of coolant 108 used, etc. As such, any numerical value provided therein is not meant to be limiting, but rather illustrative of a specific example, and it will be well within the grasp of the person of ordinary skills in the art to determine what these numeral values ought to be for a particular configuration of the cooling system 100.

In a first step 710 the IC 102 is operated at a prescribed percentage of its rated power value (referred to as X % at step 710, the power referring to the power being consumed by the IC 102 during use, the rated power of the IC 102 referring to the maximum power at which the IC 102 ought to be operated) and the fan is turned off. In some examples, at step 710 the IC is operated at less than 100% of its rated power value, for example at no more than 70% of its rated power value, in some cases at no more than 60% of its rated power value, in some cases at no more than 50% of its rated power value, in some cases at no more than 40% of its rated power value and in some cases even less. For clarity, the person skilled in the art will appreciate that the prescribed percentage of the rated power value of the IC 102 is a power in watts (W—e.g., 50% of a rated power value of 100 W corresponds to 50 W) and that such power can generally be considered an average power over a prescribed period of time.

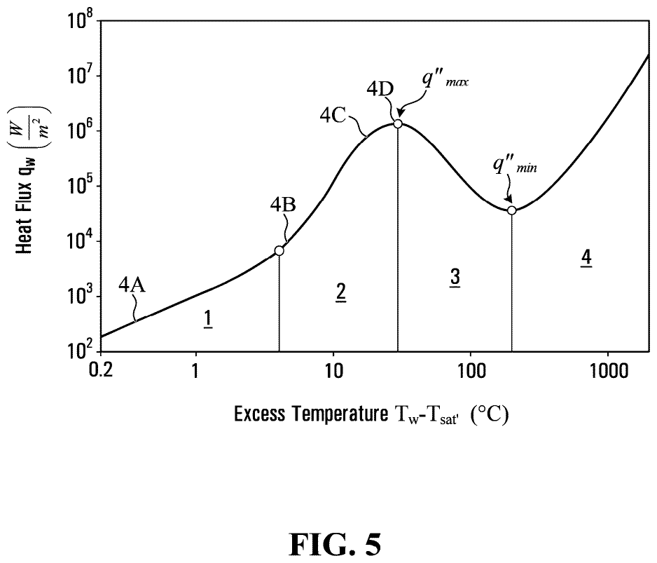

In order to do so, and with further reference to FIG. 8, the controller 106 implements a process 800 to determine whether an action is needed in terms of sending control signals to the IC 102 to modulate the power of the IC 102. In a first step 810 the controller 106 receives IC information from the IC 102 and protocol information from the memory 290. In some non-limiting examples, the IC information may notably include an IC identifier, a rated power for the IC 102 as well as an actual power (i.e., the power effectively consumed by the IC 102 at a prescribed point in time—this can be provided in the form of a percentage of the rated power of the IC 102 or in any other suitable form), a temperature of the IC 102 (in which case the IC information is derived at least in part from sensor information from a temperature sensor 110 located on the IC 102) and the likes.

The protocol information, which can be stored directly at the level of the controller 106 or even remotely in other embodiments, includes various degassing process parameters such as, but not limited to, the number of process steps and a step identifier, for each step a prescribed pressure and/or temperature (including ranges of pressure and/or temperature) within the vessel 104, a prescribed percentage of rated power for the IC 102, a prescribed temperature for the IC 102, a status for the fan 109, a number of times the pressure valve should be opened and/or closed, a prescribed time, where applicable, and the likes.

At step 820 the controller 106 implements a decision logic on the basis of the IC information and the protocol information received at step 810 to determine whether a modification of the IC power 102 is needed. This may involve a comparison between the prescribed percentage of the rated power of the IC 102 from the protocol information and the (actual) percentage of the rated power of the IC 102 from the IC information. Alternatively, this may also involve a comparison between the prescribed temperature of the IC 102 from the protocol information and the (actual) temperature of the IC 102 from the IC information. If a discrepancy is found between both values, the controller 106 determines that a modification to the power of the IC 102 is needed and then proceeds to step 830. If conversely no discrepancy is found then the process 800 ends.

At step 830, the controller 106 generates control signals at least in part based on a magnitude of the discrepancy between the prescribed percentage of the rated power of the IC 102 from the protocol information and the (actual) percentage of the rated power of the IC 102 from the IC information 9 or the magnitude of the discrepancy between the prescribed temperature of the IC 102 from the protocol information and the (actual) temperature of the IC 102 from the IC information). For example, if according to the protocol information at the first step of the degassing process the IC 102 should run at 50% of its rated power, and if according to the IC information the IC 102 currently runs at 100% of its rated power, then the controller 106 generates control signals and communicates the control signals to the IC 102 to instruct the IC 102 to reduce its power by 50%.

As such, it will readily be appreciated that, given that the temperature of the IC 102 can be correlated to the power consumed by the IC 102, and that as such the rated power of the IC 102 can be correlated to a maximum temperature of the IC 102, step 710 can be entirely performed by the controller 106 by relying on temperature data versus power data—for example, the IC 102 may also be operated at step 710 at a prescribed percentage of its maximum temperature, in which case such temperature data may be obtained via at least one temperature sensor 110 located on the IC 102.

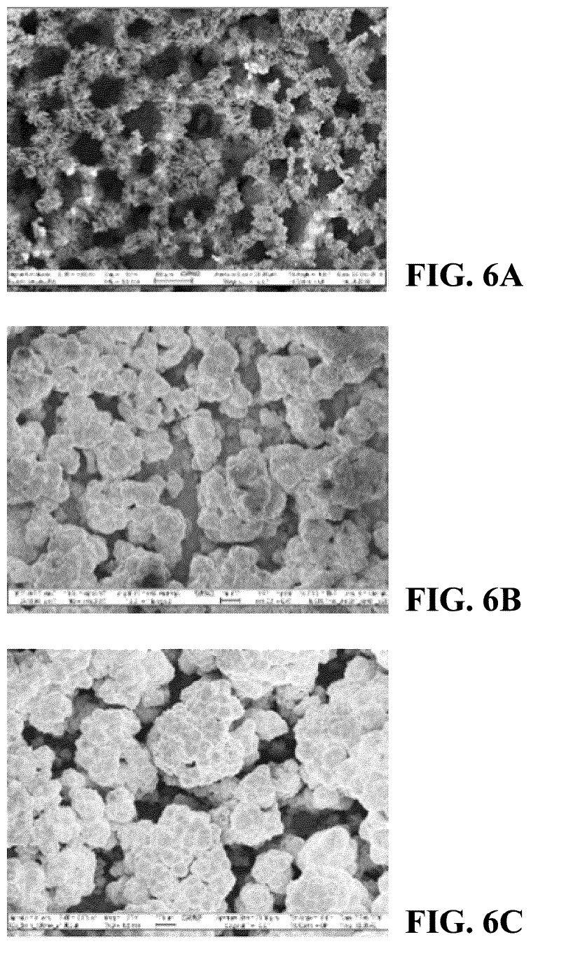

With further reference to FIG. 9, the controller 109 also implements a process 900 to determine whether an action is needed in terms of sending control signals to the fan 109 to modulate the activity of the fan. In a first step 910 the controller 106 receives fan information from the fan 109 and protocol information from the memory 290. In some non-limiting examples, the fan information may notably include a fan status (i.e., on/off) and the likes. At step 920 the controller 106 implements decision logic on the basis of the fan information and the protocol information received at step 910 to determine whether a modification of the fan 109 activity is needed. For example, if according to the protocol information at the first step of the degassing process the fan 109 should be turned off, and if according to the fan information the fan 109 is currently on, then the controller 106 generates control signals and communicates the control signals the fan 109 to turn the fan 109 off.

As such, it will be readily appreciated that at step 710 the controller 106 may send control signals via the input/output circuitry 294 to the IC 102 and/or the fan 109, as needed, based on the IC and protocol information that has been received by the controller 106 as regards the operational status of the IC 102 and the fan 109. At the end of step 710 the cooling system 100 has been set in the operational conditions conforming to those of a first step of the degassing process. As such, processes 800 and 900 are each only performed once at step 710 and up and until the controller 106 determines that the first step of the degassing process has been completed (at the end of step 720, as further described below), the controller 106 does not return to processes 800 and 900.

At step 720, the controller 106 then maintains a pressure within the vessel 104 between a first pressure value P1 and a second pressure value P2. The range of pressure defined between P1 and P2 may be any suitable range. For example, P1 may be no less than about 10 psia, in some cases no less than about 12 psia, in some cases no less than about 14 psia, in some cases no less than about 16 psia, in some cases no less than about 18, in some cases no less than about 20 psia and in some cases even more. P2 may also be no more than about 24 psia, in some cases no more than about 22 psia, in some cases no more than about 20 psia, in some cases no more than about 18 psia, in some cases no more than about 16 psia and in some cases even less.

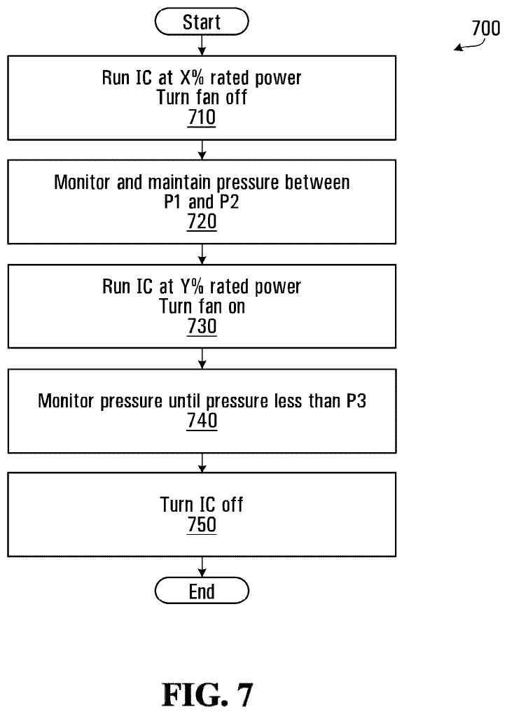

In order to do so, and with reference to FIG. 10, the controller 106 implements a process 1000 for maintaining the pressure within the vessel 104 between P1 and P2. In a first step 1010 the controller 106 receives vessel information and protocol information. In some non-limiting examples, the vessel information notably includes a pressure within the vessel 104 (in which case the vessel information is derived at least in part from sensor information from a pressure sensor 110), a status of a pressure valve (i.e., open/closed), a number of times the pressure valve has been opened and the likes and it may also be stored in the memory 290. At step 1020 the controller 106 implements decision logic to determine whether a modification of the pressure within the vessel 104 is needed such that the pressure remains between P1 and P2. This involves a comparison between the pressure within the vessel 104 and P1/P2—for example, considering P1 as the lower pressure of the two, for the controller 106 to determine that a modification of the pressure within the vessel 104 is needed the pressure within the vessel 104 needs to be less than P1 or more than P2. In the event the controller 106 determines that a modification to the pressure of the vessel 104 is needed at step 1020, the controller then proceeds to step 1030 where the controller 106 generates and communicate control signals to the valve to trigger an action.

For example, in the instance where a temperature and a pressure within the vessel 104 increase as the power of the IC 102 is maintained at its rated power (i.e., at its maximum power consumption/highest temperature)—which necessarily requires the pressure valve to be in a closed state—and therefore when the pressure within the vessel 106 reaches P2, the controller 106 will instruct the cooling system 100 to decrease the pressure within the vessel 104 to maintain the pressure between P1 and P2. To this end, the control signals generated are communicated by the controller 106 at step 1030 to the pressure valve and instruct the pressure valve to open so as to release gas from, and therefore decrease the pressure within, the vessel 104. Conversely, in the instance where the pressure valve is opened and the temperature and pressure within the vessel 104 decrease, when the pressure within the vessel 104 reaches P1 the controller will instruct the cooling system 100 to increase the pressure within the vessel 104 to maintain the pressure between P1 and P2. To this end, the control signals generated are communicated by the controller 106 at step 1030 to the pressure valve and instruct the pressure valve to close so as to stop the release gas of from, and therefore the decrease of the pressure within, the vessel 104. It will be readily appreciated that step 1030 may also include some validation by the controller 106 to the effect that prior to sending the control signals to open the pressure valve the pressure valve is in a closed state (for example, as per the vessel information). This will ensure that no redundant control signals are sent by the controller 106 to the pressure valve.

Upon completion of step 1030 or following a determination at step 1020 that no modification to the pressure within the vessel 104 is needed, the controller 106 then proceeds to step 1040 where a determination is made as to whether process 1000 should end. This determination may be made in a number of ways. For example, at each iteration the controller 106 can update the vessel information stored in the memory 290 to specify a number of times the pressure valve has been opened (e.g., at each iteration the number is increased by 1) and then compares this number to the prescribed value from the protocol information (e.g., according to the protocol the pressure valve should be opened 8 times). As long as there is no match between the two values then the controller 106 reverts to step 1010 and the process 1000 starts over. Alternatively, the controller 106 may also monitor a time since when the process 1000 originally started and compare this value to the prescribed time from the protocol information—this can be useful in the instances where such time can be correlated to the number of times the pressure valve should be opened. The controller 106 may also consider in its determination at step 1040 the state of the pressure valve (i.e., whether the pressure valve is opened or closed). For example, the controller 106 may be configured to not allow the ending of the process 1000 when the pressure valve is opened, but only to allow the ending of the process 1000 when the pressure valve is closed. It will be readily appreciated that, via step 1040, the controller 106 is continuously, or substantially continuously, running through the process 1000 for as long as no determination has been made to the effect that the process 1000 should end. The higher the frequency at which the controller 106 is performing the assessment and control operations described above in the context of the process 1000, the more granular and precise the regulation implemented by the controller 106 is.

When the controller 106 determines that the process 1000 should end then the controller 106 reverts to step 730 of FIG. 7 in which the IC 102 is operated at another prescribed percentage of its rated power value (called Y % at step 730) and the fan is turned on by the controller 106. Generally, Y≤X and in some examples at step 730 the IC 102 is operated at no more than about 10% of its rated power value, in some cases at no more than about 9% of its rated power value, in some cases at no more than about 8% of its rated power value, in some cases at no more than about 7% of its rated power value, in some cases at no more than about 6% of its rated power value, in some cases at no more than about 5% of its rated power value and in some cases even less. Much like what was described above in connection with step 710 of FIG. 7, the controller 106 also runs once through processes 800 and 900 to determine whether an action is needed in terms of sending control signals to the IC 102 to modulate the power consumed by the IC 102 (or the temperature of the IC 102, as described above) and/or in terms of sending control signals to the fan 109 to modulate the activity of the fan 109. At the end of step 730 the cooling system 100 has been set in the operational conditions conforming to those of a second step of the degassing process.

At step 740, the controller 106 then monitors the pressure within the vessel 104 until the pressure within the vessel 104 goes below a third pressure value P3. Generally, P3≤P1 and P3≤P2. For example, P3 may be no more than about 10 psia, in some cases no more than about 9 psia, in some cases no more than about 8 psia, in some cases no more than about 7 psia, in some cases no more than about 6 psia, in some cases no more than about 5 psia and in some cases even less. In this case, and contrary to what was described in the context of FIG. 10 above, the controller 106 monitors the pressure within the vessel 104 but does not actively regulate the pressure within the vessel 104.

At step 750, that is after the pressure within the vessel reaches the third pressure value P3, the controller 106 then turns off the IC 102 via the process 800 of FIG. 8, the fan 109 remaining on. This effectively sets the operational conditions conforming to those of a third and last step of the degassing process. From a perspective of the process 700, in some examples the process 700 ends as soon as the IC 102 has been turned off by the controller 106 at step 740. More broadly however, the degassing process may practically continue longer up and until the cooling system 100 has reached thermodynamic equilibrium, at which point the pressure within the vessel 104 will be lower than the atmospheric pressure and the liquid coolant 108 substantially free of non-condensable gas, as described above. As such, in other non-limiting examples, the controller 106 may also optionally implement a delay function that will prevent the IC 102 from being turned on for a prescribed period of time (which can, for example, be stored in the protocol information) after the IC 102 has been turned off by the controller 106 at step 740—this will practically ensure that the cooling system 100 will reach equilibrium, and therefore that the degassing process is complete, prior to the IC 102 being turned on again. Any suitable period of time may be defined by the controller 106, such as but not limited to at least about 10 minutes, in some cases at least about 15 mins, in some cases at least about 20 mins, in some cases at least about 30 mins, in some cases at least about 40 mins and in some cases even more.

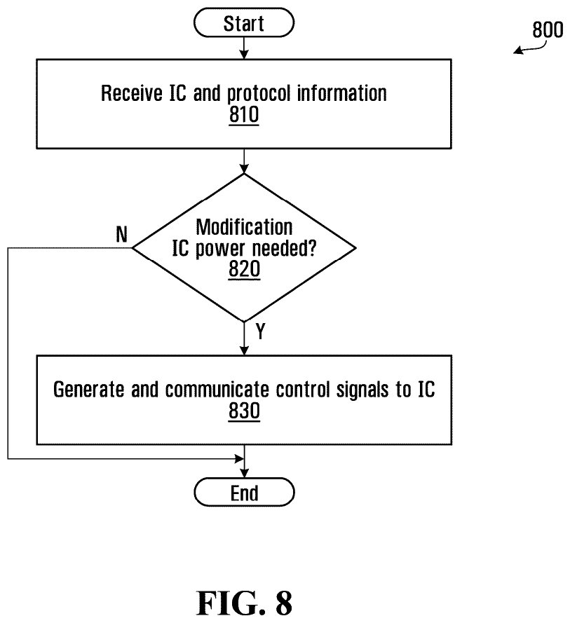

In some embodiments, and with further reference to FIG. 11, the controller 106 may also be configured to further implement a process 1100 to determine whether the gas seal integrity of the cooling system 100 has been compromised (i.e., whether the cooling system 100 suffers from any leak). In some non-limiting examples, this can be achieved using the vessel information which, as described above, can notably include the pressure within the vessel 104 and the status of the pressure valve. At step 1110, using both the pressure within the vessel 104 and the status of the pressure valve the controller 106 can determine whether a decrease in pressure within the vessel 104 when the valve is not opened is or is not associated with a reduction of the power of the IC 102 or of a temperature of the IC 102. In other words, when the pressure valve is closed and no gas escapes the vessel 104 via the pressure valve, a decrease in the pressure within the vessel 104 while the power/temperature of the IC 102 is constant or increases can only be indicative of a leak in the cooling system 100, and therefore of an absence of gas seal integrity. Since this would have a negative effect on the performance and the overall efficacy of the process 700, the process 1100 can be run by the controller 106 continuously, or substantially continuously, and concurrently with the process 700 described above, up and until the IC 102 is turned off. When gas seal integrity is found at step 1110, the process 1100 repeats itself up and until the IC 102 is turned off. When an absence of gas seal integrity is found at step 1110, the controller 106 then proceeds to step 1120 where an action is taken by the controller 106 before repeating the process 1100. A variety of actions may be performed—these notably include, but are not limited to, throttling or turning off the IC 102, terminating the process 700 and the likes.

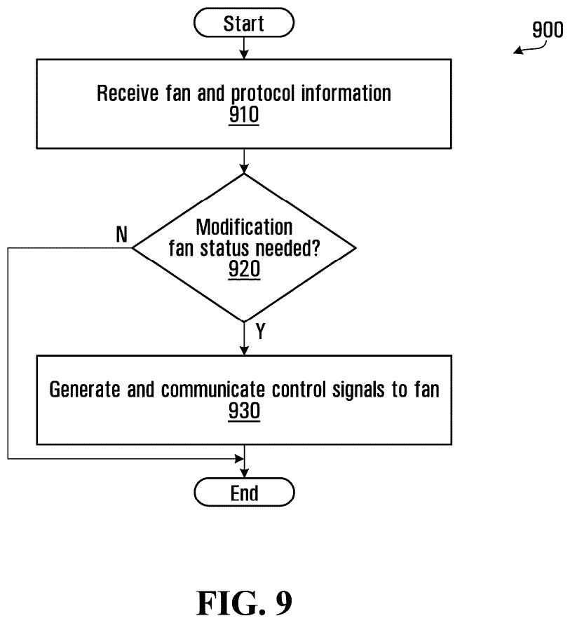

It will be readily appreciated that the protocol 700 should only be performed once on a given cooling system 100 for as long as the gas seal integrity of the cooling system 100 is maintained, i.e. for as long as the vessel 104 remains a sealed compartment post-degassing. In other words, it is not necessary for the controller 106 to perform the process 700 each and every time the IC 102 is turned on. To this end, and with further reference to FIG. 12, the controller 106 is further configured to implement a process 1200 for self-degassing of the cooling system 100. In a first step 1210, and prior to running the process 700, when the IC 102 is turned on the controller 106 first determines whether the process 700 has already been run on the IC 102. This can be done in a number of ways, for example the controller 106 may consult the vessel information stored in the memory 290 to determine whether the number of times the pressure valve has been opened is non-nil, consult any record generated by the controller 106 and stored in the memory 294 to the effect that process 700 has been performed once, etc.

Heat Flow from IC to Coolant

As at least part or at least one surface of the IC 102 is thermally coupled to the coolant 108, heat flows from the IC 102 to coolant 108, when the IC 102 is running. This flow of heat from the IC 102 to the coolant 108 constitutes the heat flux, which is the rate of heat energy transferred through a given surface per unit time. Of relevance, the heat energy transits through at least one element that exhibits some thermal resistance in the system, namely the IHS 122, as further described below.

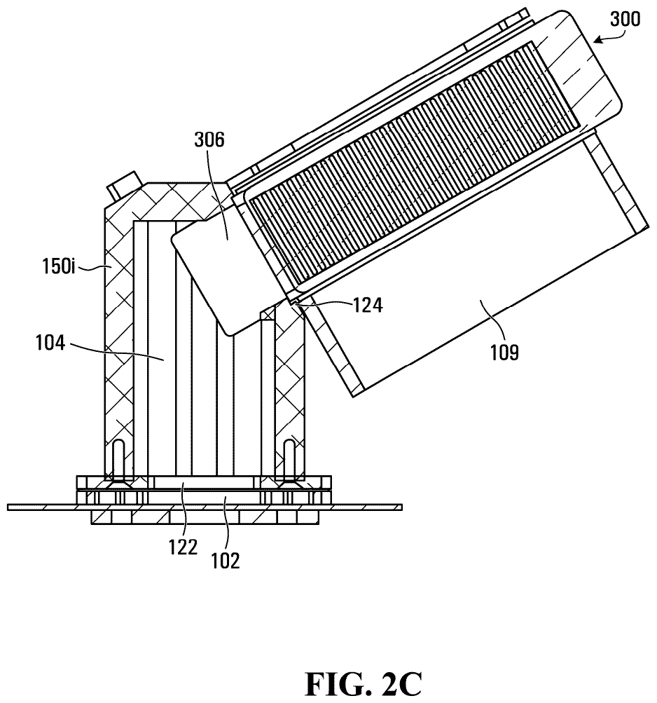

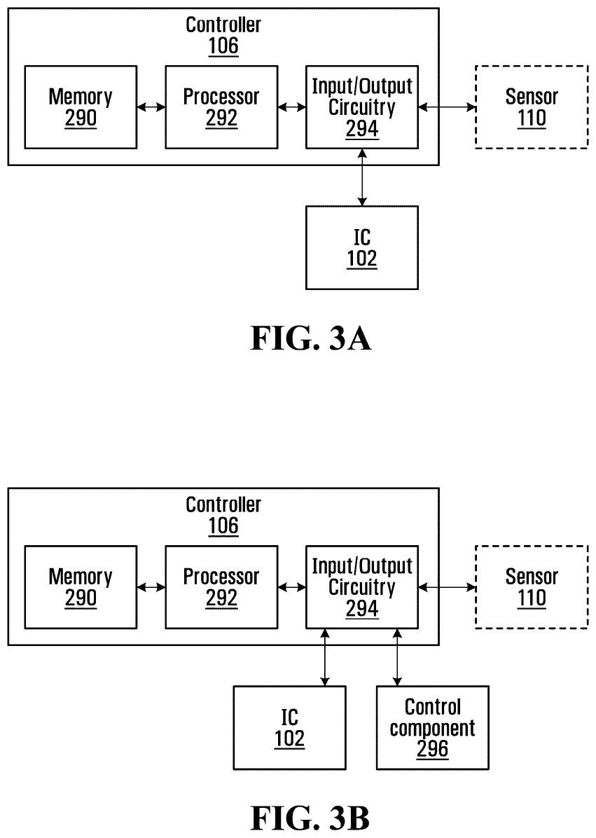

The heat flow mechanics from the IC 102 to the coolant 108 will now be described by reference to FIGS. 4A to 4D and FIG. 5. FIGS. 4A to 4D illustrate specific and non-limiting examples of the coolant 108 in various states of phase change as heat flows from the IC 102 to the coolant 108, via the IHS 122. FIG. 5 illustrates a specific and non-limiting example of a heat flux curve for the heat transfer from the IC 102 to the coolant 108. Heat flux is the rate of heat energy transfer through a given surface per unit time, in this example the heat flux is the rate of heat energy transferred through the surface of the IC 102 per unit time. The x-axis of the graph in FIG. 5 is the excess temperature, T_{w}−T_{sat′} (in Celsius), where T_{w} is the surface temperature of the IC 102 and T_{sat′} is saturated fluid temperature of the coolant 108, and the y-axis of the graph is the heat flux, q_{w}″ (W/m²). The excess temperature corresponds to a difference between the surface temperature of the IC 102 in relation to a saturated fluid temperature of the coolant 108. FIG. 5 shows four regions 1, 2, 3 and 4, where in the first region 1 natural heat convection occurs, which is illustrated in FIG. 4A. Then in region 2, nucleate boiling occurs. Nucleate boiling is a type of boiling that takes place when the surface temperature of the IC 102 is hotter than the saturated fluid temperature of the coolant 108 by a certain amount. At first isolated bubbles 212 occur, as shown in FIG. 4B, and then as the excess temperature increases columns and slugs 214 occur, as shown in FIG. 4C. Then at the burnout point, qₘₐₓ″ the bubbles collapse into a substantially continuous dry film 216, leading to a dry IC 102, which is shown in FIG. 4D. In region 3, transition boiling occurs which may include unstable film and partial nucleate boiling and then in region 4, film boiling occurs.

Considering FIGS. 4A to 4D and FIG. 5 in further detail, thermal energy is directed from the IC 102 to the adjoining liquid coolant 108 (via the IHS 122) and defines the heat flux from the IC 102 into the coolant 108. At first, thermal energy that is directed from the IC 102 to the adjoining liquid coolant 108, which has the effect of elevating the temperature of the liquid coolant 108 via convection heat transfer. FIG. 4A illustrates an example where convection heat transfer from the IC 102 to the coolant 108 is occurring. When heat flows from the IC 102 to the coolant 108, the temperature of the coolant 108 increases, to the point where vapor bubbles 212 nucleate at the surface of the IC 102, as shown in FIG. 4B. As such, a phase change occurs that takes up the thermal energy from the IC 102. In other words, when the temperature of the IC 102 exceeds the boiling point of the liquid coolant 108, it causes the liquid coolant 108 to evaporate. The latent heat of vaporization associated with this phase transition helps increase the magnitude of the heat flow from the IC 102 to the liquid coolant 108 beyond the heat flow due to convection. This process is most efficient when the bubbles 212 nucleate easily, and when they also detach easily. After detachment, the bubbles 212 generally rise in the liquid coolant 108 (due to buoyancy forces), and therefore contribute to transporting heat away from the IC 102. A number of regimes can thus be observed in the cooling process: (i) at low IC surface temperatures, bubbles do not form, and heat is transported by convection in the liquid coolant 108 (e.g., as in FIG. 4A); (ii) as the IC surface temperature increases, bubbles nucleate and detach at an increasing rate, leading to efficient heat transfer (e.g., as in FIG. 4B); (iii) the density of bubbles on the IC surface becomes large at higher IC surface temperatures (e.g., as in FIG. 4C), and the bubbles collapse to form a continuous film (e.g., as in FIG. 4D), leading to a dry IC surface and less efficient heat transfer; (iv) at very high temperatures, conduction and radiation heat transfer through the vapor film eventually lead to high heat fluxes again. The maximum heat flux at the end of regime (iii) is called the “critical heat flux” (CHF), indicated by qₘₐₓ″ in FIG. 5. Passed that operational point, the heat flux decreases as the excess temperature increases. It is essentially a thermal runaway condition where heat is no longer efficiently removed from the IC surface, which can damage the IC.

The specific critical heat flux value for the setup shown in FIG. 1 may be for instance defined by the setup parameters of the cooling system 100, such as but not limited to the physical properties of the coolant 108, the characteristics of the heat exchanging surface 104₁, the characteristic of the IHS 122 and the pressure among others.

The CHF shown in FIG. 5 by qₘₐₓ″ corresponds to heat flux measured in a steady-state situation, where power has been applied to the IC 102 for a long enough time for the heat flux to have stabilized. In transient conditions, heat transfer inertia between the heat input of the IC 102 and the response of the liquid coolant 108 exists. This heat transfer inertia defines a window of time during which the heat flux can exceed the steady-state CHF value without creating a burnout. In other words, during that window the coolant 108 is able to absorb the heat flux, which exceeds the steady-state CHF value for the particular setup, but without the bubbles collapsing to form a dry surface. As such, one aspect of some embodiments described herein is to periodically increase the heat output produced by the IC 102 in order to temporarily produce a heat flux above the steady-state CHF value. The heat output of the IC 102 is then lowered, but before a burn out occurs. The process can be repeated indefinitely.

The heat flux is a value that cannot be readily measured. However, the heat flux can be correlated to the temperature of the IC 102 surface. For a given setup, the heat flux can be computed and the temperature at which the CHF occurs, determined. Then by monitoring the temperature of the IC 102 surface, one can determine the operational point relative to the CHF. With reference to regions 1 and 2 in FIG. 5, as the temperature of the IC 102 increases the steady-state heat flux of the IC 102 into the coolant 108 also increases until a maximum is reached; thereafter, as the temperature of the IC 102 increases the steady-state heat flux of the IC 102 into the coolant 108 decreases, as shown in region 3 in FIG. 5. As such, an aspect of some embodiments described herein is to monitor the surface temperature of the IC 102 and manage the operational parameters of the IC 102 based on the identified surface temperature of the IC 102 at which CHF is reached.

### IHS

The IHS 122 thermally couples the IC 102 to the liquid coolant 108 within the vessel 104, the IHS 122 thereby defining at least one region having a thermal resistance between the IC 102 and the coolant 108. To this end, the IHS 122 is attached onto the at least part or at least one surface 124 of the IC 102. Any suitable connection mean may be used, such as but not limited to thermal paste, indium soldering and the likes. To ensure the gas seal integrity of the vessel 104, the IHS 122 is also sealed to the vessel 104, specifically to the neighboring portions of respective ones of the plurality of walls 150; using any suitable sealing mean. It will be readily appreciated that, contrary to the heat sink 112, the IHS 122 does not itself retain a significant amount of heat, but rather distributes or conducts heat generated by the IC 102 towards the coolant 108. This transfer of heat energy from the IC 102 to the coolant 108 can be facilitated and/or improved in a number of ways, as further described below.

In this non-limiting embodiment, the IHS 122 has horizontal (i.e., x and y) and vertical (i.e., z) dimensions. That is, in the non-limiting example in which the IHS 122 has the general shape of a cuboid, the IHS 122 has a length, a width and a depth. The characterization of IHS 122 may be made according to the geometrical configuration and the composition of the IHS 122, as well as to the (heat transfer) properties of the IHS 122, as further described below.

In one non-limiting example, the IHS 122 may have a homogeneous composition and be made of any suitable material, such as but not limited to a metallic material such as copper, nickel and the likes, a composite material or any other suitable material. In other non-limiting examples, the composition of the IHS 122 may be heterogeneous and the IHS 122 may be made of at least two different materials, such as but not limited to two different metallic materials, a metallic material and a ceramic material, and the likes. In some non-limiting examples, the heterogeneous composition of the IHS 122 may be obtained by electroplating a first metallic material with a second metallic material, such as but not limited to copper electroplated with nickel, nickel electroplated with copper and the likes. It will be readily appreciated that electroplating may also be used to produce IHS 122 with homogeneous compositions, for example nickel electroplated with nickel or copper electroplated with copper, although these homogeneous compositions may also exhibit properties that are different from the ones of the IHS 122 with the same metallic composition but without any electroplating, as further described below. Beyond electroplating, other surface treatment processes may also be used, alone or in combination with other surface treatment processes, and which also result in the IHS 122 having a heterogeneous composition, such as but not limited to various coatings, including coating with microporous metallic boiling enhancement (BEC) sold by 3M, electroplating, the soldering of a metallic porous surface onto the IHS 122, the machining of small fin on the IHS 122 and the likes. The various methods described above may be performed directly on the IHS 122 which overlays the IC 102 (i.e., the IHS 122 is electroplated as it overlays the IC 102, which would be the case for a variety of IC 102 that are commercially available with the IHS 122), or they may also be performed on various layers and/or films of metallic material which are then secured to the IC 102 using any suitable securing method such as brazing and the likes.

The IHS 122 may have any suitable shape and/or dimension, for example the IHS 122 may be a cube or a cuboid. In the horizontal dimension, the IHS 122 may have any suitable surface of contact with the liquid coolant 108. In one non-limiting example, in the horizontal dimension the IHS 122 may have a surface of contact with the liquid coolant 108 that is less than 150 cm.sup.2, in some cases less than 125 cm.sup.2, in some cases less than 100 cm.sup.2, in some cases less than 75 cm.sup.2, in some cases less than 50 cm.sup.2, in some cases less than 25 cm.sup.2 and in some cases even less. It will be readily appreciated that, as further described below, the overall cooling capacity of the IHS 122 is dependent upon the surface of the IHS 122, i.e. the larger the IHS 122 surface of contact with the liquid coolant 108 the greater the cooling capacity of the IHS 122.

The IHS 122 may also have any suitable thickness. In one non-limiting example, the IHS 122 may have a thickness of less than 10 mm, in some cases less than 9 mm, in some cases less than 8 mm, in some cases less than 7 mm, in some cases less than 6 mm, in some cases less than 5 mm, in some cases less than 4 mm, in some cases less than 3 mm and in some cases even less. Where applicable, the thickness of the IHS 122 includes that of any surface treatment of the IHS 122, which itself contributes to an increase in its thickness as further described below. It will be readily appreciated that the thickness of the IHS 122 needs not be identical along the entire surface of the IHS 122. That is, in some embodiments, the IHS 122 may exhibit a varying thickness in at least one of the x and the y directions. For example, the IHS 122 may exhibit a decreasing thickness profile from a center of the IHS 122 towards a periphery of the IHS 122 in at least one of the x and y directions. In other examples, the IHS 122 may exhibit an increasing thickness profile from a center of the IHS 122 towards a periphery of the IHS 122 in at least one of the x and y directions.

In this embodiment, the shape of the IHS 122 being generally that of a cube or a cuboid, the surface of contact between the IHS 122 and the liquid coolant 108 is generally planar, that is it is substantially straight in both the x and y directions. This however needs not be the case in other embodiments in which the surface of contact between the IHS 122 and the liquid coolant 108 may have any suitable shape. For example, in the z direction the surface of contact between the IHS 122 and the liquid coolant 108 may exhibit a generally curved or Gaussian profile.

Electroplating and/or coating of the IHS 122, as described above, may also facilitate the heat transfer from the IHS 122 to the liquid coolant 108, for example by facilitating bubble formation and bubble release. More specifically, electroplating and/or coating may be used to create a porous layer on the IHS 122 that will increase the surface area of the IHS 122/coolant 108 interface. In this context, the IHS 122 may be characterized in a number of ways, including but not limited to a porosity (which as used herein refers to a fraction of void within the porous layer) and a pore size distribution (which as used herein refers to the distribution of various pore sizes in a unit volume of the porous layer), more specifically a porosity and a pore size distribution within the region of the IHS 122 that constitutes the porous layer.

As regards pore size distribution, in some non-limiting examples the pores are generally dimensioned such that the average pore size is larger than the average bubble size. In this fashion, bubbles are less likely to become trapped in the porous layer. Bubble formation may induce an isolation layer due to the fact that heat transfer is less through gas than through liquid. The bubble starts small and increases in size until the point where the force of differential density is larger than the force of adhesion of the bubble surface to the surface of the IHS 122. Hence the bubble should be carried away as fast as possible once created. Another feature of the porous layer is to increase the heat transfer coefficient, thereby increasing the heat flux at the IHS 122/coolant 108 interface, as further described below. The porous layer can have a random and generally uniform pore size distribution or the pore size distribution can be controlled to create a pore-size gradient, as further described below. The pore size gradient may be such that the pore size generally increases with the distance from the surface of the IC 102. In other words, the pores that are closer to the surface of the IC 102 are the smallest and moving further away from the IC 102 the pores become increasingly larger. Small pores create a larger heat exchange surface and also provide more nucleation sites for bubble formation. As bubbles are created and released from the smaller pores, they travel through larger pores which owing to their size provide a larger escape pathway to prevent bubble trapping. The pore-size gradient employed should allow for high heat transfer and ease of bubble extraction at the IHS 122/coolant 108 interface.

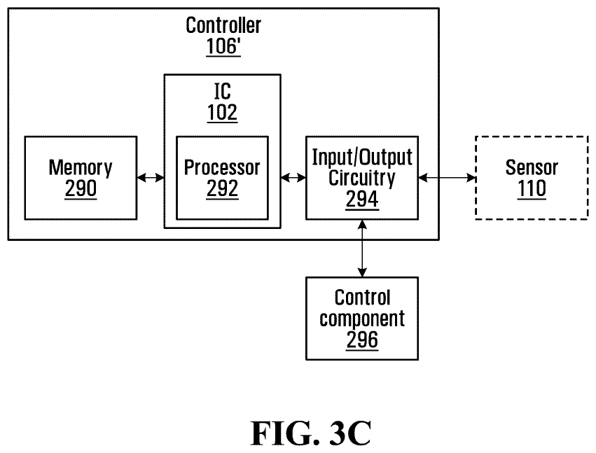

As regards porosity, it may be measured in a number of ways, for example by manually processing scanning electron microscope (SEM) images of the surface of the IHS 122 using the ImageJ image and processing software (using a variety of thresholds set forth by the user) or automatically by processing the SEM images of the surface of the IHS 122 using the PorJ extension in ImageJ. In some non-limiting examples, after electroplating a porosity at a surface of the IHS 122 may be less 40%, in some cases less than 35%, in some cases less than 30% and in some cases even less. It will be readily appreciated that, and with further reference to FIGS. 6A-6C, much like the pore-size distribution above, the porosity of the IHS 122 may also not be homogeneous in the horizontal and/or vertical directions. That is, the porosity of the IHS 122 may for example vary according to whether, in a horizontal plane, the porosity is measured at a center or around the periphery of the IHS 122 (in which case the porosity is always measured at a top of the porous layer) or whether, in a vertical plane, the porosity is measured at a top or at a center of the porous layer. In other words, the porous layer of the IHS 122 may also exhibit gradients of porosity in the horizontal (i.e., x and y) and/or vertical (i.e., z) directions, and such gradients will themselves be reliant upon the general dimensions of the IHS 122 in the x, y and z directions. In the examples of FIGS. 6A-6C, the porous layer exhibits a decreasing porosity profile from a center of the layer in the z direction towards a top of the layer in the z direction (see e.g., FIGS. 6A and 6B). The porous layer also exhibits a decreasing porosity profile from a center of the porous layer towards a periphery of the porous layer (see, e.g. FIGS. 6B and 6C).

In some non-limiting examples, a porosity at a periphery of the IHS 122 may be 20% less than of a porosity at a center of the IHS 122 (the center being defined according to the general shape in the horizontal plane of the IHS 122, both porosities being measured at a top of the porous layer), in some cases 17.5% less than of a porosity at a center of the IHS 122, in some cases 15% less than of a porosity at a center of the IHS 122, in some cases 12.5% less than of a porosity at a center of the IHS 122, in some cases 10% less than of a porosity at a center of the IHS 122, in some cases 7.5% less than of a porosity at a center of the IHS 122 and in some cases even less. That is, in these non-limiting examples, the porosity of the IHS 122 generally decreases away from the center of the porous layer.

In other non-limiting examples, a porosity at a top of the porous layer of the IHS 122 may be 30% less than of a porosity at a center of the porous layer of the IHS 122 (in the z direction), in some cases 25% less than of a porosity at a center of the porous layer of the IHS 122, in some cases 20% less than of a porosity at a center of the porous layer of the IHS 122, in some cases 15% less than of a porosity at a center of the porous layer of the IHS 122, and in some cases even less. That is, in these non-limiting examples, the porosity of the IHS 122 generally increases away from the top of the porous layer.

In one non-limiting embodiment, the IHS 122 may exhibit a thermal resistance of no more than about 0.4° C./W for a power of the IC 102 of about 45 W, in some cases no more than about 0.38° C./W for a power of the IC 102 of about 45 W, in some cases no more than about 0.36° C./W for a power of the IC 102 of about 45 W, in some cases no more than about 0.35° C./W for a power of the IC 102 of about 45 W, in some cases no more than about 0.34° C./W for a power of the IC 102 of about 45 W and in some cases even less.

In another non-limiting embodiment, the IHS 122 may exhibit a thermal resistance of no more than about 0.36° C./W for a power of the IC 102 of about 67 W, in some cases no more than about 0.34° C./W for a power of the IC 102 of about 67 W, in some cases no more than about 0.32° C./W for a power of the IC 102 of about 67 W, in some cases no more than about 0.31° C./W for a power of the IC 102 of about 67 W, in some cases no more than about 0.30° C./W for a power of the IC 102 of about 67 W in some cases no more than about 0.29° C./W for a power of the IC 102 of about 67 W and in some cases even less.

In yet a further non-limiting embodiment, the IHS 122 may exhibit a thermal resistance of no more than about 0.33° C./W for a power of the IC 102 of about 88 W, in some cases no more than about 0.31° C./W for a power of the IC 102 of about 88 W, in some cases no more than about 0.29° C./W for a power of the IC 102 of about 88 W, in some cases no more than about 0.28° C./W for a power of the IC 102 of about 88 W, in some cases no more than about 0.27° C./W for a power of the IC 102 of about 88 W, in some cases no more than about 0.26° C./W for a power of the IC 102 of about 88 Wand in some cases even less.

In yet a further non-limiting embodiment, the IHS 122 may exhibit a thermal resistance of no more than about 0.29° C./W for a power of the IC 102 of about 110 W, in some cases no more than about 0.27° C./W for a power of the IC 102 of about 110 W, in some cases no more than about 0.25° C./W for a power of the IC 102 of about 110 W, in some cases no more than about 0.24° C./W for a power of the IC 102 of about 110 W, in some cases no more than about 0.23° C./W for a power of the IC 102 of about 110 W, in some cases no more than about 0.22° C./W for a power of the IC 102 of about 110 W and in some cases even less.

### Example 1—Degassing Protocol

A cooling system was provided for cooling a 110 W CPU. The cooling system included a vessel having a height of about 14 cm configured to receive a volume of about 50 mL of 3M™ Novec™ 649 dielectric coolant as well as a heat sink (having a plurality of fins) with a fan installed thereon to further facilitate heat transfer. The cooling system was first filled with the dielectric coolant and was then sealed to define a fixed volume within the vessel, the vessel being loaded with about 50 mL of dielectric coolant containing non-condensable gas.

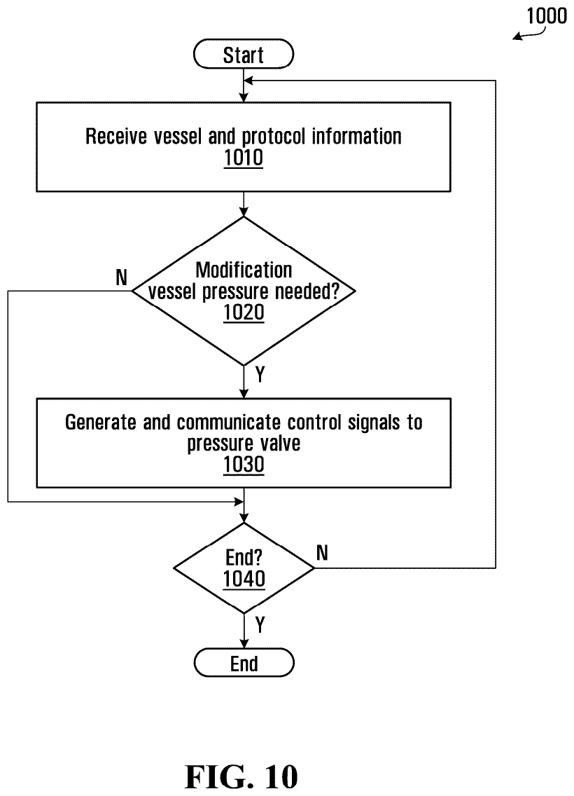

With further reference to FIG. 13, the degassing protocol for the dielectric coolant was performed as follows. In a first step, the CPU was run at about 50% of its rated power, that is for a CPU of 110 W at about 50 W, and the fan is turned off. The pressure within the vessel was monitored and was kept between about 16 and 18 psia at all times (with Novec™ 649). In other words, upon running the CPU at about 50% of its rated power the pressure within the vessel increases—when the pressure reaches about 18 psia a pressure valve in the cooling system is opened to release some gas from the vessel and bring the pressure within the vessel down to about 16 psia, at which point the pressure valve is closed and pressure rises again. In this first step the sequence above is repeated 8 times.

In a second step the fan is turned on and the CPU is run at about 5% of its rated power, that is for a CPU of 110 W at about 6 W. The pressure within the vessel decreases and is left to decrease until the pressure within the vessel has reached about 6.5 psia (with Novec™ 649).

In a third step, once the pressure within the vessel has reached about 6.5 psia the CPU is shut down with the fan remaining on. Once the system has reached thermodynamic equilibrium in at least about 20 minutes, degassing is complete and the pressure within the vessel is below atmospheric pressure.

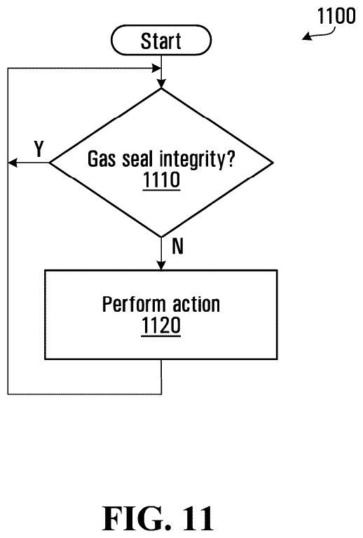

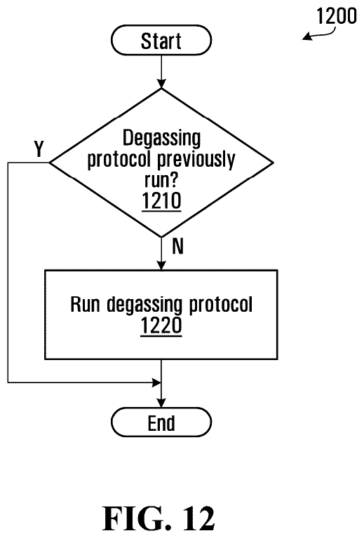

A variant of the cooling system according to another embodiment of the invention is illustrated in FIG. 14. The cooling system 1400 is designed as an independent module that can be installed on an IC, either at the time of the manufacture of the PCB or afterwards to retrofit the PCB with an upgraded cooling system. FIG. 15 provides an exploded view from different perspectives of the cooling system 1400, illustrating its main components.

The cooling system 1400 has a base 1402 that defines a chamber for holding the cooling liquid. The chamber has a circular lower portion and a rectangular upper portion. The rectangular upper portion is an easier geometric configuration to mate with a condenser that has typically a rectangular arrangement.

The cooling system 1400 further includes a contact plate 1404 which implements the heath transfer pathway between the IC and the coolant, and in this example includes the integrated heat spreader described earlier. The contact plate 1404 is of generally circular configuration and mounts to the lower edge of the chamber 1402. The contact plate is sealed to the chamber 1402 via a suitable gasket.

On the upper end of the chamber 1402 is mounted a condenser to perform condensation of the gaseous medium in the chamber. The condenser 1406 has a lower condenser plate 1408, an upper condenser plate 1410, an array of fluid transport channels 1412 and a fin block 1416 that meshes with the array of fluid transport channels 1412 to allow an efficient heath dissipation from the fluid transport channels to the atmosphere. It will be noted that the fin block is manufactured as a unit and has one pair of studs at each corner: there being one stud projecting upwardly and one stud projecting downwardly. Collectively the studs allow mounting the covers and the condenser plate to the base 1402 with fasteners, such as nuts when the studs are threaded.

More specifically, a lower condenser plate 1418 is provided to mate the condenser 1406 to the base 1402, while allowing fluid to enter the respective channels of the condenser 1406. Accordingly, the lower condenser plate 1418 allows the individual channels to communicate with the internal space of the chamber below such that gas can rise into the channels where it condensates and the condensed liquid will flow into the channels back to the chamber.

Note, for mass produced units the channels array 1412 and the fin block 1416 would typically be made as a single unit; the channels brazed or otherwise secured to the arrangement of fins.

A gasket 1420 is provided to seal the lower condenser plate to the chamber 1402. An upper condenser plate 1410 closes the channels of the array 1412 at their top ends. In this specific example of implementation, the upper condenser plate 1410 also closes the top ends of the respective channels.

A top cover 1422 closes the assembly. The top cover 1422 is secured in place with nuts threadedly mounted on the studs on the fin block 1416. The entire assembly is fastened with nuts to the upper edge portion of the chamber 1402.

A fan 1424 is provided to force air to circulate through the fin block 1416. The fan 1424 is mounted to the side of the fin block 1416.

The chamber 1402 is mounted to the IC to be cooled via a socket 1426 that enables a mechanical connection between the IC and the cooling system.

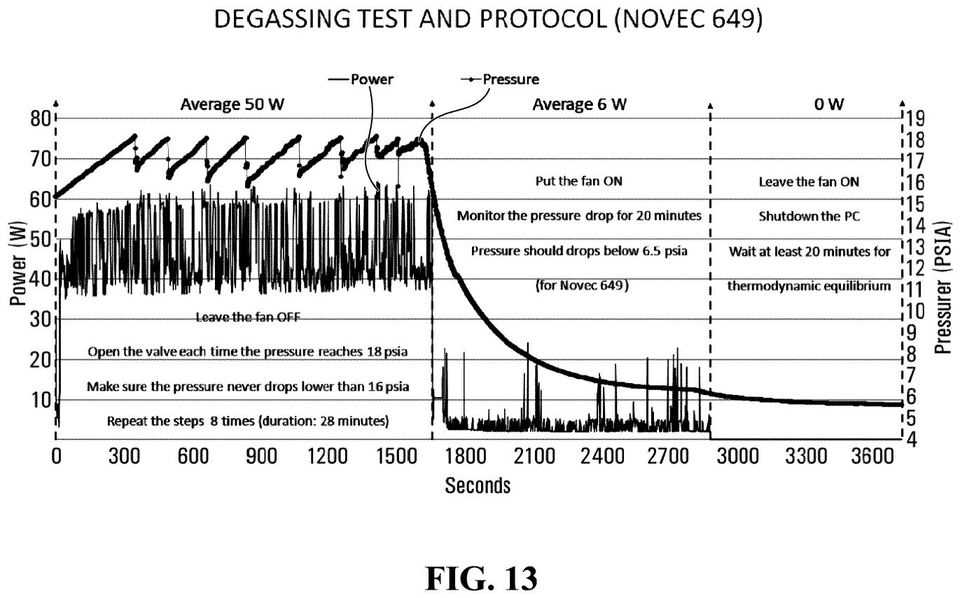

FIG. 16 illustrates two possible contact plate versions that can be used depending on the socket type and the IC type. The version at the left is configured for a cooling system that is assembled and degassed at the factory and only needs to be physically coupled to the IC, such as, as a traditional 4U heath sink. In this version the contact plate is has a continuous surface that is uninterrupted to create a fluid-tight seal between the chamber 1402 and the IC. To mount the cooling system to the IC socket, thermal paste is applied on the upper surface of the IC and the cooling system is attached to the socket with mechanical fasteners. In this example of implementation, the thermal pathway to the cooling liquid in the chamber 1402 includes the contact plate and the thermal paste which objectively is undesirable as these components introduce some degree of thermal resistance.

The second version of the contact plate is shown at the right in FIG. 16. It has an aperture that is designed to accommodate the IC such that the top surface of the IC is in direct contact with the liquid in the chamber 1402. In this example, the cutout in the contact plate tightly matches the IC body such as to be able to create a fluid tight seal between the contact plate and the periphery of the IC. In practice, since a range of IC body sizes are available in the industry, a range of different contact plates would be made available to match the form factor of the IC to cool. All the contact plates will have different cut-out shapes and the installer will need to match the proper cut-out plate to the IC form factor.

The second version of the contact plate provides superior cooling performance since the thermal resistance between the IC and the cooling liquid is less as there is direct contact between the IC and the cooling liquid. The downside to this approach is the necessity to set-up the system as it cannot be pre-filled with cooling liquid at the factory, as is the case with the first version of the contact plate.

The specification described previously an example of implementation where the set-up of the system, which includes the degassing of the cooling liquid is done once the cooling system is mounted on the IC and the fluid tight seal between the IC and the interior of the chamber 1402 established. This procedure can be used in this example to set-up the system.

Alternatively, the cooling liquid can be degassed separately, outside of the cooling chamber 1402, such that the cooling chamber 1402 can be directly filled with degassed cooling liquid after the chamber 1402 is mounted and sealed on the IC. To avoid the contamination of the degassed liquid with environmental gases that may be present in the chamber 1402, the latter should be purged such as by pumping the gaseous medium out with a vacuum pump. Once, the chamber is so purged, the degassing cooling liquid is introduced in the chamber 1402. At that point, the cooling system is ready of use.

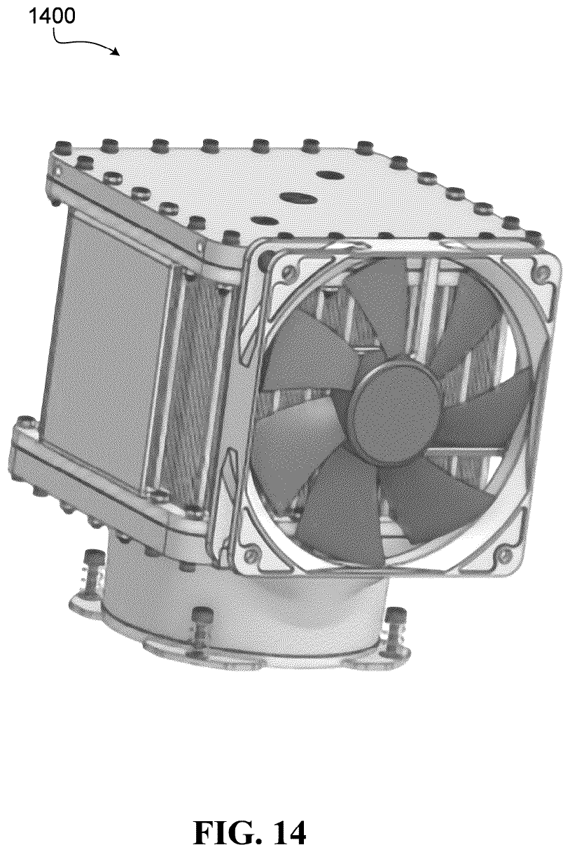

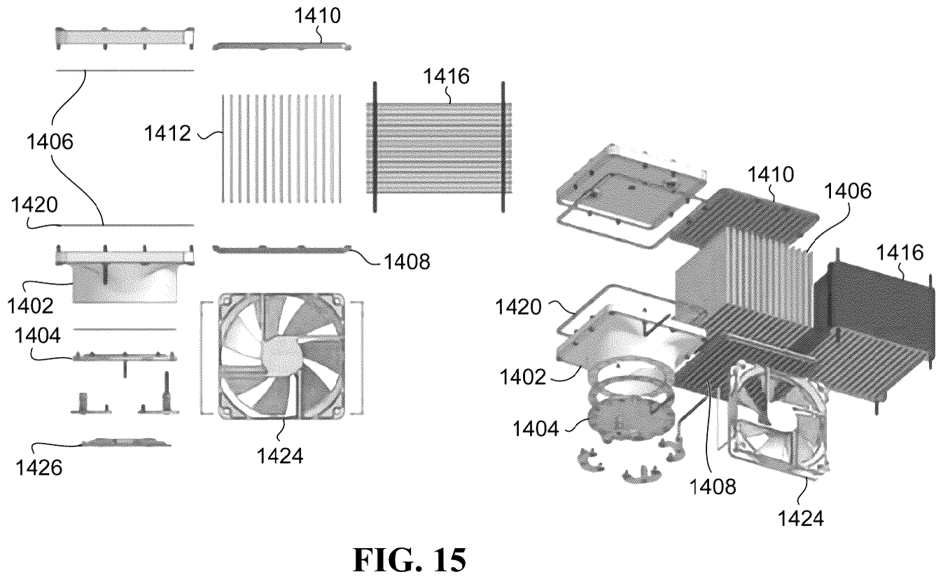

FIGS. 17 and 18 provide an example of a set-up that can be used to degase the cooling liquid outside the chamber 1402 and then introduce it into the chamber 1402 after the latter has been mounted to sealed to the IC. The degassing apparatus has a vessel 1700 for holding non-degassed cooling liquid. A heat-source 1702, such as an electric heating element heats the cooling liquid in the vessel 1700. Pressure and temperature gages 1704 are provided to monitor the degassing operation. In use, the vessel 1700 is filled to the desired level with cooling liquid and the heat source 1702 actuated to heat the liquid at the desired temperature. When the desired temperature and pressure in the vessel 1700 are reached, the port 1706 is opened to release the gas pressure in the vessel 1700, thus release a major component of the non-condensable gases that have been evaporated from the cooling liquid. At that point the cooling liquid is degassed and can be used in the cooling system. Specifically, as described earlier, the procedure may include purging the inside of the chamber 1402 with a vacuum pump and then pouring the cooling liquid in the chamber 1402 from the vessel 1700 via an exit port 1708. When the chamber 1402 is filled to the desired level through a suitable inlet port, the latter is closed to establish a fluid tight seal and prevent contaminants to ingress the chamber 1402.

Alternatively, instead of degassing the cooling liquid at the point of assembly of the cooling system to the IC, the cooling liquid can be degassed separately and made available in a container to fill the chamber 1402. The container can be any suitable container, such as a plastic bag provided with an outlet port allowing to release the degassed liquid to the chamber 1402 without contamination from the external gaseous atmosphere. To further simplify the filling operation, the degassing liquid can be made available in pre-measured quantities and only requires that the chamber 1402 is purged and the pre-measured dose of degassed cooling liquid is introduced in the chamber 1402 by connecting the outlet of the flexible plastic bag to the inlet port of the chamber 1402.

In a yet another embodiment, the degassed liquid is held in an individual container that is physically attached to the cooling system and the container is opened to fill the chamber 1402 after the chamber is purged, in order to fill the chamber. This avoids any external manipulation necessary to introduce the degassed liquid into the chamber 1402.

FIG. 34 illustrates this arrangement. At the site of manufacture of the cooling system, the cooling liquid chamber 1402 is assembled with condenser 1406, which is provided on the top plate thereof with a one-way vacuum sensitive valve 2400 that establishes a pathway between the condenser 1406 and a cooling liquid pack, such as flexible bag filled with a quantity of degassed cooling liquid pre-determined to fill the chamber 1402 at the desired fill level. The assembly thus arrives as a unit with the cooling liquid pack.

The cooling system is then mounted to the IC as described previously and the seal between the IC the cooling liquid chamber 1402 established. A vacuum pump is connected to the cooling liquid chamber 1402 to suck out the gaseous content and thus purge the chamber. The one-way vacuum sensitive valve is calibrated such as to open at a vacuum level corresponding to one where a sufficient level of purge is achieved. As the valve 2400 opens, the degassed liquid will flow into the chamber 1402. The vacuum pump is then the stopped and the purge port is closed. The flexible bag 2402, which is now empty can be removed from the valve 2400 that will close and keep the system isolated and ready for operation. The empty bag can be discarded.

In another example of implementation, the surface of the contact plate that is in contact with the cooling liquid is provided with a Multi-Scale Electroplated Porous (MuSEP) structure to enhance the boiling performance of the highly wetting cooling liquid. Multi-step electroplating with current variation at each step yields a random particle formation where small particles lay at the bottom, and the bigger particles arrange themselves on the top. This specific structure triggers the bubble formation at low power, which results in shortening the natural convection regime. The large particles on the top play two significant roles at high power; wicking the liquid toward the nucleation sites and spacing the nucleation sites to prohibit bubble merging.

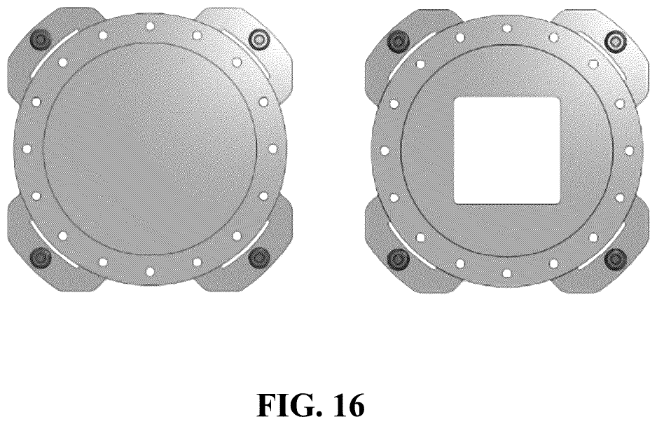

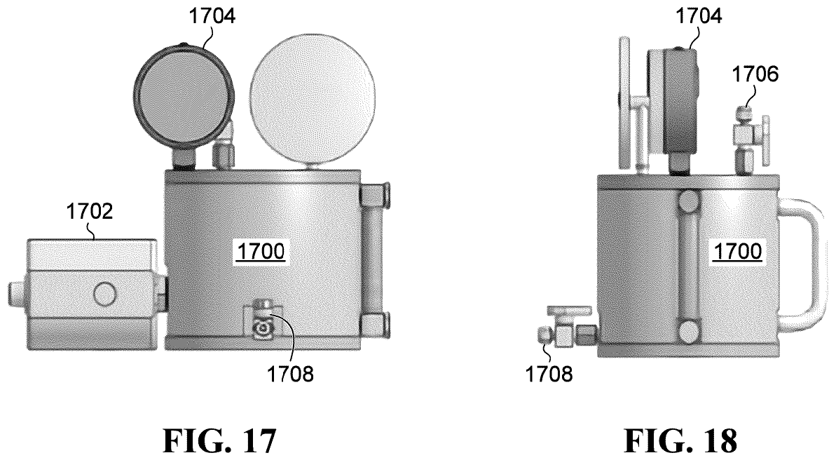

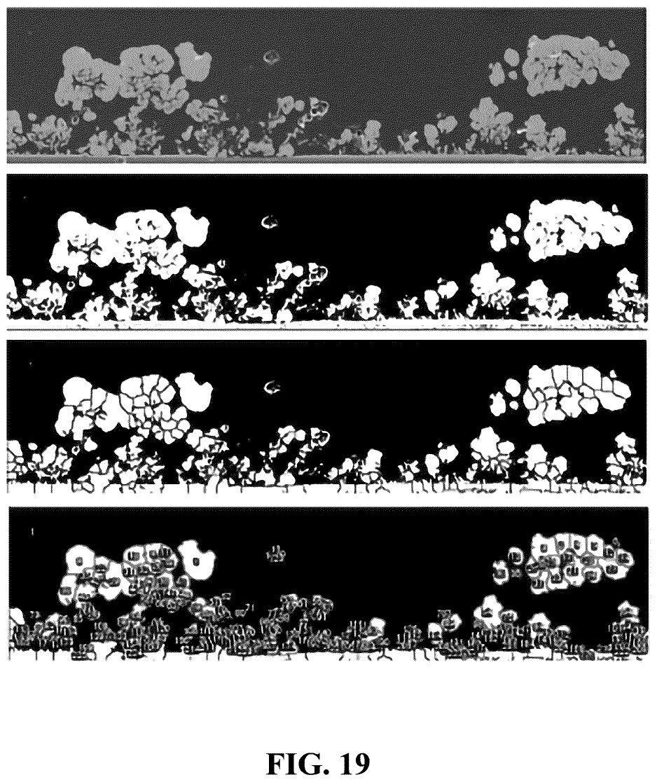

With reference to FIGS. 19, 20 and 21, the analysis of particles distribution has been done using ImageJ software. The porosity was calculated 49.4% from the side view. The image also shows the small pores at the bottom, which are protected by the large particles on the top. The particles are distributed from small to large in the upward direction. Almost 50% of the particles have a size of less than 15 micrometers. The thickness of the coated layer is around 500 micrometers, and the porosity was calculated 49.4%.

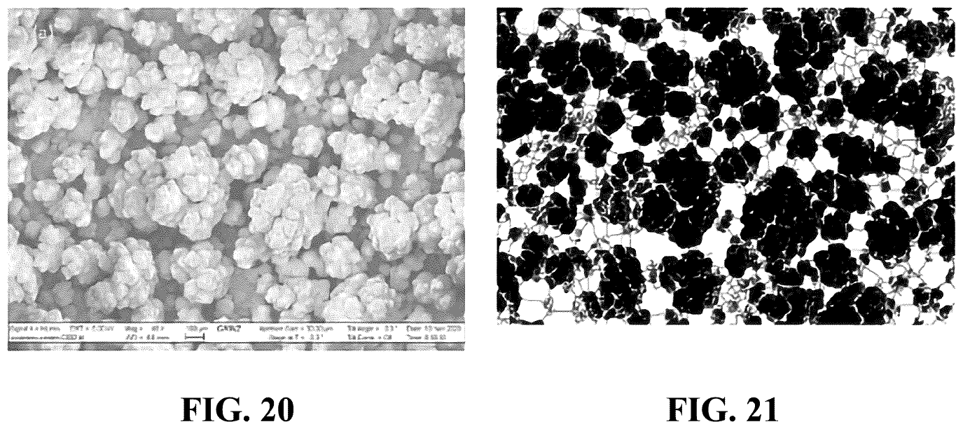

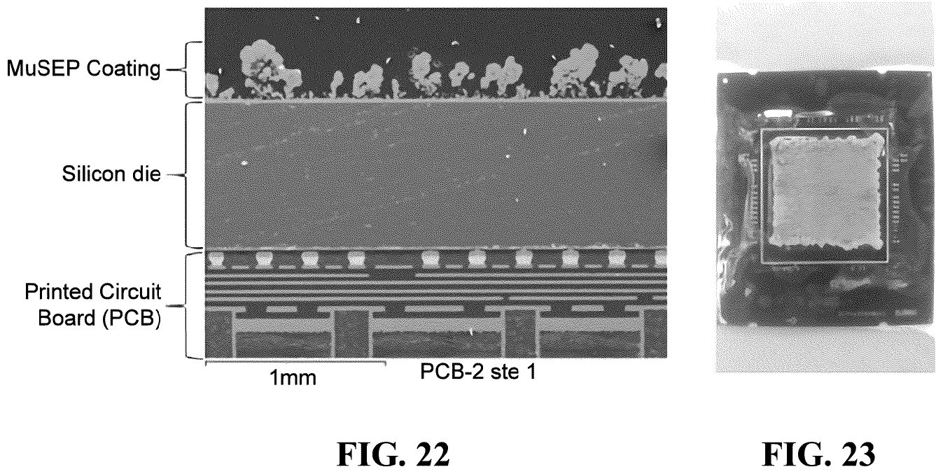

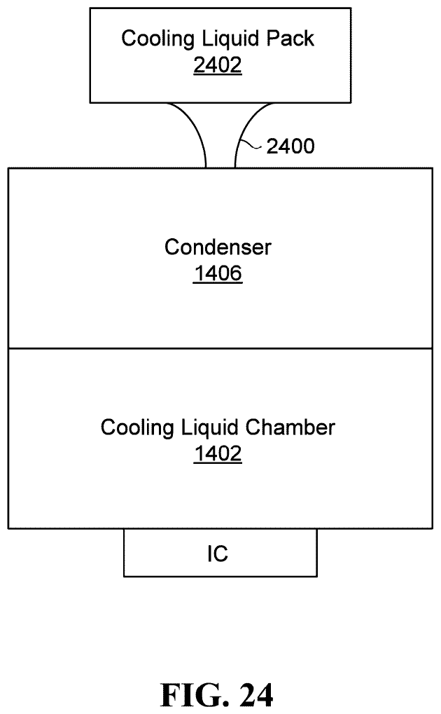

FIGS. 22 and 23 illustrate a further embodiment of the invention where the top surface of the silicon die of the IC has been directly coated to form the porous structure, such as the MuSEP structure described earlier, it being understood that other porous structures can be used without departing from the spirit of the invention.

Specifically, FIG. 22 shows from bottom to top in cross-section the PCB arrangement and the silicon die resting on the PCB. The upper surface of the silicon die is provided with the MuSEP coating which enables boiling of the cooling liquid to occur directly at the top of the die. In this arrangement, there is a material continuum from the silicon to the cooling liquid providing an efficient heat transport pathway, free of material junctions that add thermal resistance.

The application of the MuSEP coating involves processing the silicon die as a substrate during the coating process. That is to say, the upper surface of the silicon die is exposed during the coating process such as to allow the deposition of the various layers of the coating to form the porous structure shown in FIG. 22 and FIGS. 19, 20 and 21, strongly bonded to the silicon material.

Certain additional elements that may be needed for operation of some embodiments have not been described or illustrated as they are assumed to be within the purview of those of ordinary skill in the art. Moreover, certain embodiments may be free of, may lack and/or may function without any element that is not specifically disclosed herein.

Any feature of any embodiment discussed herein may be combined with any feature of any other embodiment discussed herein in some examples of implementation.

The use of headings in the document is for illustrative purposes only and is not intended to be limiting.

Although various embodiments and examples have been presented, this was for the purpose of describing, but not limiting, the invention. Various modifications and enhancements will become apparent to those of ordinary skill in the art and are within the scope of the invention, which is defined by the appended claims.

1. A method for making a system for cooling an integrated circuit (IC), the method comprising:
a) providing a closed vessel for holding a coolant in a liquid phase, the vessel being delimited at least in part by a heat transfer region configured to be thermally-coupled with the IC at a heat-transfer interface of the heat-transfer region; and
b) providing the heat transfer region with a Multi-Scale Electroplated Porous (MuSEP) structure formed by a multi-step electroplating process, comprising:
i. electroplating, at a first step, a first porous layer; and
ii. electroplating, at second step, a second porous layer; and
iii. varying a deposition current between the first and second steps to create larger pores further from the heat transfer interface, thereby yielding a MuSEP structure with a pore-size gradient where the pore size increases in a direction away from the heat-transfer interface.

2. The method of claim 1, wherein the MuSEP structure comprises particles of increasing size in a direction away from the heat-transfer interface.

3. The method of claim 2, wherein IC comprises a silicon die, the MuSEP structure being electrodeposited on the silicon die such that the heat-transfer interface is in direct contact with the silicon die.

4. The method of claim 2, wherein the MuSEP structure is made of metal.

5. The method of claim 2, further comprising providing the vessel with a condenser to condense boiled coolant.

6. The method of claim 2, further comprising a mechanical connector for securing the IC to the heat-transfer region, such that an external surface of the IC is in contact with the heat-transfer interface.

7. A method as defined in claim 2, wherein the IC is selected in the group consisting of, CPU, GPU, FGPA and ASIC.

8. The method of claim 2, further comprising introducing a liquid coolant into the vessel such that the coolant is in direct contact with the MuSEP structure.

9. The method of claim 8, further comprising:
a. sealing the vessel after filling it with the coolant;
b. operating the IC to heat the coolant;
c. opening a valve to release gases from the vessel including a non-condensable gas fraction from the vessel;
d. closing the valve; and
e. operating the system to cool the IC, wherein the vessel is free of the non-condensable gas fraction.
